(19) United States
(12) Patent Application Publication
(10) Pub. No.: US 2024/0394444 A1
(43) Pub. Date: Nov. 28, 2024

(54) BUILDING MANAGEMENT SYSTEM WITH GOAL-BASED SENSOR PLAN GENERATION

(71) Applicant: Tyco Fire & Security GmbH, Neuhausen am Rheinfall (CH)

(72) Inventors: Trent M. Swanson, Wellington, FL (US); Miguel Galvez, Westford, MA (US); Vineet Binodshanker Sinha, Brookfield, WI (US); Kaleb Luedtke, West Bend, WI (US); Prashanthi Sudhakar, San Francisco, CA (US); John T. Pierson, Whitefish Bay, WI (US)

(21) Appl. No.: 18/674,447

(22) Filed: May 24, 2024

Related U.S. Application Data
(60) Provisional application No. 63/469,324, filed on May 26, 2023.

(51) Int. Cl. G06F 30/27; G06F 40/20

(52) U.S. Cl. CPC G06F 30/27; G06F 40/20

(57) ABSTRACT

Systems and methods are disclosed relating to building management systems with goal-based sensor plan generation. For example, a method can include receiving data relating to a layout of a space of a building and/or one or more sensors of the building. The method can further include determining, using an artificial intelligence (AI) model, a goal for the space. The method can further include autonomously generating, using the AI model, a proposed sensor plan for the space based on the data and the goal without requiring manual user intervention. The method can further include providing the proposed sensor plan to a user.

### CROSS-REFERENCE TO RELATED APPLICATIONS

This application claims the benefit of and priority to U.S. Patent Application No. 63/469,324, filed May 26, 2023, the entire disclosure of which is incorporated by reference herein.

### BACKGROUND

This application relates generally to a building system of a building. This application relates more particularly to systems for managing and processing data of the building system.

A variety of sensors are utilized in building monitoring settings to capture information regarding and/or monitor various aspects of building operations. For example, audio or video capturing devices may be utilized to capture sound and/or video of various spaces within buildings. Similarly, a variety of other sensor types may be utilized to detect or otherwise monitor air quality, temperature, humidity, particulate levels, occupancy, etc. within buildings. However, determining optimal placements of sensors for various spaces poses a variety of challenges. Specifically, it has traditionally been difficult to determine an optimal number and layout of sensors within a given space due to various conflicting goals and/or regulations associated with the space and the intended data to be collected.

### SUMMARY

Systems and methods are disclosed relating to building management systems with goal-based sensor plan generation. One aspect relates to a method. The method includes receiving, by one or more processors, data relating to a layout of a space of a building and/or one or more first sensors of the building. The method further includes determining, by the one or more processors using an artificial intelligence (AI) model, a goal for the space. The method further includes autonomously generating, by the one or more processors using the AI model, a proposed sensor plan for the space based on the data and the goal, the proposed sensor plan comprising at least one of utilization and/or placement of the one or more first sensors within the space, addition of one or more second sensors to the space, or utilization of one or more additional data sources to supplement data from the one or more first sensors for the space, wherein autonomously generating the proposed sensor plan comprises generating the proposed sensor plan using the AI model based on the data and the goal without requiring manual user intervention. The method further includes providing, by the one or more processors, the proposed sensor plan to a user.

Another aspect relates to a system. The system includes one or more processing circuits having one or more processors and one or more memories. The one or more memories have instructions thereon that, when executed by the one or more processors, cause the one or more processors to: receive data relating to a layout of a space of a building and/or one or more first sensors of the building. The instructions, when executed by the one or more processors, further cause the one or more processors to determine, using an artificial intelligence (AI) model, a goal for the space based on the data. The instructions, when executed by the one or more processors, further cause the one or more processors to autonomously generate, using the AI model, a proposed sensor plan for the space based on the data and the goal, the proposed sensor plan comprising at least one of utilization and/or placement of the one or more first sensors within the space or addition of one or more second sensors to the space, wherein autonomously generating the proposed sensor plan comprises generating the proposed sensor plan using the AI model based on the data and the goal without requiring manual user intervention. The instructions, when executed by the one or more processors, further cause the one or more processors to provide the proposed sensor plan to a user.

Yet another aspect relates to a non-transitory computer-readable storage medium having instructions stored thereon that, when executed by one or more processors, cause the one or more processors to receive data relating to a layout of a space of a building and/or one or more first sensors of the building. The instructions, when executed by the one or more processors, further cause the one or more processors to determine, using a generative artificial intelligence (GAI) model, a goal for the space based on the data. The instructions, when executed by the one or more processors, further cause the one or more processors to autonomously generate, using the GAI model, a proposed sensor plan for the space based on the data and the goal, the proposed sensor plan comprising at least one of utilization and/or placement of the one or more first sensors within the space or addition of one or more second sensors to the space, wherein autonomously generating the proposed sensor plan comprises generating the proposed sensor plan using the GAI model based on the data and the goal without requiring manual user intervention. The instructions, when executed by the one or more processors, further cause the one or more processors to provide the proposed sensor plan to a user.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a block diagram of an example of a machine learning model-based system for equipment servicing applications.

FIG. 2 is a block diagram of an example of a language model-based system for equipment servicing applications.

FIG. 3 is a block diagram of an example of the system of FIG. 2 including user application session components.

FIG. 4 is a block diagram of an example of the system of FIG. 2 including feedback training components.

FIG. 5 is a block diagram of an example of the system of FIG. 2 including data filters.

FIG. 6 is a block diagram of an example of the system of FIG. 2 including data validation components.

FIG. 7 is a block diagram of an example of the system of FIG. 2 including expert review and intervention components.

FIG. 8 is a flow diagram of a method of generating a goal-based sensor plan.

### DETAILED DESCRIPTION

Referring generally to the FIGURES, systems and methods in accordance with the present disclosure can implement various systems to precisely generate data relating to operations to be performed for managing building systems and components and/or items of equipment, including heating, ventilation, cooling, and/or refrigeration (HVAC-R) systems and components. For example, various systems described herein can be implemented to more precisely generate data for various applications including, for example and without limitation, virtual assistance for having a variety of proposed sensor layouts for a given space generated autonomously. Various such applications can further facilitate autonomously generating natural language text-based descriptions, natural language audible descriptions, two-dimensional images, and/or three-dimensional graphical model representations of the proposed sensor layouts shown within the building or overlaid onto an image or graphical model thereof. The applications can further allow for the user to provide various feedback (e.g., text-based or verbal natural language feedback, feedback via interaction with a graphical user interface) regarding the proposed sensor plans, and to autonomously generate modified proposed sensor layouts in response to the user's feedback.

AI and/or machine learning (ML) systems, including but not limited to LLMs or other generative AI models (e.g., transformer models, such as generative pretrained transformers, generative adversarial networks, etc.), can be used to generate text data and data of other modalities in a more responsive manner to real-time conditions, including generating strings of text data that may not be provided in the same manner in existing documents, yet may still meet criteria for useful text information, such as relevance, style, and coherence. For example, LLMs can predict text data based at least on inputted prompts and by being configured (e.g., trained, modified, updated, fine-tuned) according to training data representative of the text data to predict or otherwise generate.

However, various considerations may limit the ability of such systems to precisely generate appropriate data for specific conditions. For example, due to the predictive nature of the generated data, some LLMs may generate text data that is incorrect, imprecise, or not relevant to the specific conditions. Using the LLMs may require a user to manually vary the content and/or syntax of inputs provided to the LLMs (e.g., vary inputted prompts) until the output of the LLMs meets various objective or subjective criteria of the user. The LLMs can have token limits for sizes of inputted text during training and/or runtime/inference operations (and relaxing or increasing such limits may require increased computational processing, API calls to LLM services, and/or memory usage), limiting the ability of the LLMs to be effectively configured or operated using large amounts of raw data or otherwise unstructured data.

Systems and methods in accordance with the present disclosure can use machine learning models, including LLMs and other generative AI systems, to capture data, including but not limited to unstructured knowledge from various data sources, and process the data to accurately generate outputs, such as completions responsive to prompts, including in structured data formats for various applications and use cases. The system can implement various automated and/or expert-based thresholds and data quality management processes to improve the accuracy and quality of generated outputs and update training of the machine learning models accordingly. The system can enable real-time messaging and/or conversational interfaces for users to provide various data regarding equipment, sensors, and/or other spaces within the building to the system (including presenting targeted queries to users that are expected to elicit relevant responses for efficiently receiving useful response information from users) and guide users, such as site planners or other equipment or sensor installation managers, through various sensor layout planning processes for planning sensor layouts within given spaces within a building.

In some instances, significant computational resources (or human user resources) can be required to process data relating to various differing building spaces, sensor layouts, and corresponding sensor layout characteristics (e.g., efficiency, sensor coverage within given building spaces, sustainability, cost) to determine appropriate goals for new building spaces and optimized sensor layouts for achieving those goals. Systems and methods in accordance with the present disclosure can leverage the efficiency of language models (e.g., GPT-based models or other pre-trained LLMs) in extracting semantic information (e.g., semantic information identifying characteristics of space within buildings, current sensor layouts within various spaces, and other accurate information regarding relevant spaces within buildings) from the unstructured data in order to use the unstructured data, data relating to relevant spaces within the building, and data relating to the various equipment/sensors within the building to generate more useful proposed sensor plans/layouts for the relevant spaces. While various implementations are described as being implemented using generative AI models such as transformers and/or GANs, in some embodiments, various features described herein can be implemented using non-generative AI models or even without using AI/machine learning, and all such modifications fall within the scope of the present disclosure.

In various implementations, the systems can include a plurality of machine learning models that may be configured using integrated or disparate data sources. This can facilitate more integrated user experiences or more specialized (and/or lower computational usage for) data processing and output generation. Outputs from one or more first systems, such as one or more first algorithms or machine learning models, can be provided at least as part of inputs to one or more second systems, such as one or more second algorithms or machine learning models. For example, a first language model can be configured to process unstructured inputs (e.g., text, speech, images, etc.) into a structure output format compatible for use by a second system, such as a sensor plan/layout generator and/or a visualization generator model.

### I. Machine Learning Models for Building Management and Goal-Based Sensor Plan/Layout Generation

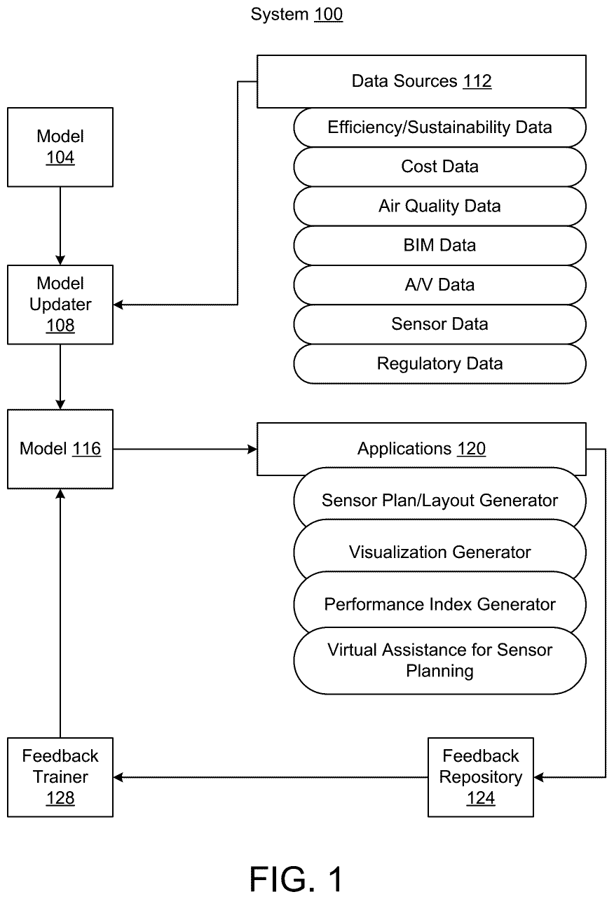

FIG. 1 depicts an example of a system 100. The system 100 can implement various operations for configuring (e.g., training, updating, modifying, transfer learning, fine-tuning, etc.) and/or operating various AI and/or ML systems, such as neural networks of LLMs or other generative AI systems. The system 100 can be used to implement various generative AI-based building equipment servicing operations.

For example, the system 100 can be implemented for operations associated with any of a variety of building management systems (BMSs) or equipment or components thereof. A BMS can include a system of devices that can control, monitor, and manage equipment in or around a building or building area. The BMS can include, for example, a HVAC system, a security system, a lighting system, a fire alerting system, any other system that is capable of managing building functions or devices, or any combination thereof. The BMS can include or be coupled with items of equipment, for example and without limitation, such as heaters, chillers, boilers, air handling units, sensors, actuators, refrigeration systems, fans, blowers, heat exchangers, energy storage devices, condensers, valves, or various combinations thereof.

The items of equipment can operate in accordance with various qualitative and quantitative parameters, variables, setpoints, and/or thresholds or other criteria, for example. In some instances, the system 100 and/or the items of equipment can include or be coupled with one or more controllers for controlling parameters of the items of equipment, such as to receive control commands for controlling operation of the items of equipment via one or more wired, wireless, and/or user interfaces of controller.

Various components of the system 100 or portions thereof can be implemented by one or more processors coupled with or more memory devices (memory). The processors can be a general purpose or specific purpose processors, an application specific integrated circuit (ASIC), one or more field programmable gate arrays (FPGAs), a group of processing components, or other suitable processing components. The processors may be configured to execute computer code and/or instructions stored in the memories or received from other computer readable media (e.g., CDROM, network storage, a remote server, etc.). The processors can be configured in various computer architectures, such as graphics processing units (GPUs), distributed computing architectures, cloud server architectures, client-server architectures, or various combinations thereof. One or more first processors can be implemented by a first device, such as an edge device, and one or more second processors can be implemented by a second device, such as a server or other device that is communicatively coupled with the first device and may have greater processor and/or memory resources.

The memories can include one or more devices (e.g., memory units, memory devices, storage devices, etc.) for storing data and/or computer code for completing and/or facilitating the various processes described in the present disclosure. The memories can include random access memory (RAM), read-only memory (ROM), hard drive storage, temporary storage, non-volatile memory, flash memory, optical memory, or any other suitable memory for storing software objects and/or computer instructions. The memories can include database components, object code components, script components, or any other type of information structure for supporting the various activities and information structures described in the present disclosure. The memories can be communicably connected to the processors and can include computer code for executing (e.g., by the processors) one or more processes described herein.

### Machine Learning Models

The system 100 can include or be coupled with one or more first models 104. The first model 104 can include one or more neural networks, including neural networks configured as generative models. For example, the first model 104 can predict or generate new data (e.g., artificial data; synthetic data; data not explicitly represented in data used for configuring the first model 104). The first model 104 can generate any of a variety of modalities of data, such as text, speech, audio, images, video, and/or graphical model data. The neural network can include a plurality of nodes, which may be arranged in layers for providing outputs of one or more nodes of one layer as inputs to one or more nodes of another layer. The neural network can include one or more input layers, one or more hidden layers, and one or more output layers. Each node can include or be associated with parameters such as weights, biases, and/or thresholds, representing how the node can perform computations to process inputs to generate outputs. The parameters of the nodes can be configured by various learning or training operations, such as unsupervised learning, weakly supervised learning, semi-supervised learning, or supervised learning.

The first model 104 can include, for example and without limitation, one or more language models, LLMs, attention-based neural networks, transformer-based neural networks, generative pretrained transformer (GPT) models, bidirectional encoder representations from transformers (BERT) models, encoder/decoder models, sequence to sequence models, autoencoder models, generative adversarial networks (GANs), convolutional neural networks (CNNs), recurrent neural networks (RNNs), diffusion models (e.g., denoising diffusion probabilistic models (DDPMs)), or various combinations thereof.

For example, the first model 104 can include at least one GPT model. The GPT model can receive an input sequence, and can parse the input sequence to determine a sequence of tokens (e.g., words or other semantic units of the input sequence, such as by using Byte Pair Encoding tokenization). The GPT model can include or be coupled with a vocabulary of tokens, which can be represented as a one-hot encoding vector, where each token of the vocabulary has a corresponding index in the encoding vector; as such, the GPT model can convert the input sequence into a modified input sequence, such as by applying an embedding matrix to the tokens of the input sequence (e.g., using a neural network embedding function), and/or applying positional encoding (e.g., sin-cosine positional encoding) to the tokens of the input sequence. The GPT model can process the modified input sequence to determine a next token in the sequence (e.g., to append to the end of the sequence), such as by determining probability scores indicating the likelihood of one or more candidate tokens being the next token, and selecting the next token according to the probability scores (e.g., selecting the candidate token having the highest probability scores as the next token). For example, the GPT model can apply various attention and/or transformer based operations or networks to the modified input sequence to identify relationships between tokens for detecting the next token to form the output sequence.

The first model 104 can include at least one diffusion model, which can be used to generate image and/or video data. For example, the diffusional model can include a denoising neural network and/or a denoising diffusion probabilistic model neural network. The denoising neural network can be configured by applying noise to one or more training data elements (e.g., images, video frames) to generate noised data, providing the noised data as input to a candidate denoising neural network, causing the candidate denoising neural network to modify the noised data according to a denoising schedule, evaluating a convergence condition based on comparing the modified noised data with the training data instances, and modifying the candidate denoising neural network according to the convergence condition (e.g., modifying weights and/or biases of one or more layers of the neural network). In some implementations, the first model 104 includes a plurality of generative models, such as GPT and diffusion models, that can be trained separately or jointly to facilitate generating multi-modal outputs, such as technical documents (e.g., service guides) that include both text and image/video information.

In some implementations, the first model 104 can be configured using various unsupervised and/or supervised training operations. The first model 104 can be configured using training data from various domain-agnostic and/or domain-specific data sources, including but not limited to various forms of text, speech, audio, image, video, and/or graphical model data, or various combinations thereof. The training data can include a plurality of training data elements (e.g., training data instances). Each training data element can be arranged in structured or unstructured formats; for example, the training data element can include an example output mapped to an example input, such as a query representing a service request or one or more portions of a service request, and a response representing data provided responsive to the query. The training data can include data that is not separated into input and output subsets (e.g., for configuring the first model 104 to perform clustering, classification, or other unsupervised ML operations). The training data can include human-labeled information, including but not limited to feedback regarding outputs of the models 104, 116. This can allow the system 100 to generate more human-like outputs.

In some implementations, the training data includes data relating to building management systems. For example, the training data can include examples of HVAC-R data, such as operating manuals, technical data sheets, configuration settings, operating setpoints, diagnostic guides, troubleshooting guides, user reports, technician reports. In some implementations, the training data used to configure the first model 104 includes at least some publicly accessible data, such as data retrievable via the Internet. In some implementations, the training data used to configure the first model 104 includes captured data (e.g., audio, video, other sensor data) pertaining to and/or captured from a variety of buildings including, for example, data relating to sensor plans and/or sensor layouts. The training data may also include additional information pertaining to various sensor plans and layouts, such as, for example, power consumption data, efficiency data, sensor coverage information, etc. regarding various sensor plans and layouts.

Referring further to FIG. 1, the system 100 can configure the first model 104 to determine one or more second models 116. For example, the system 100 can include a model updater 108 that configures (e.g., trains, updates, modifies, fine-tunes, etc.) the first model 104 to determine the one or more second models 116. In some implementations, the second model 116 can be used to provide application-specific outputs, such as outputs having greater precision, accuracy, or other metrics, relative to the first model, for targeted applications.

The second model 116 can be similar to the first model 104. For example, the second model 116 can have a similar or identical backbone or neural network architecture as the first model 104. In some implementations, the first model 104 and the second model 116 each include generative AI machine learning models, such as LLMs (e.g., GPT-based LLMs) and/or diffusion models. The second model 116 can be configured using processes analogous to those described for configuring the first model 104.

In some implementations, the model updater 108 can perform operations on at least one of the first model 104 or the second model 116 via one or more interfaces, such as application programming interfaces (APIs). For example, the models 104, 116 can be operated and maintained by one or more systems separate from the system 100. The model updater 108 can provide training data to the first model 104, via the API, to determine the second model 116 based on the first model 104 and the training data. The model updater 108 can control various training parameters or hyperparameters (e.g., learning rates, etc.) by providing instructions via the API to manage configuring the second model 116 using the first model 104.

### Data Sources

The model updater 108 can determine the second model 116 using data from one or more data sources 112. For example, the system 100 can determine the second model 116 by modifying the first model 104 using data from the one or more data sources 112. The data sources 112 can include or be coupled with any of a variety of integrated or disparate databases, data warehouses, digital twin data structures (e.g., digital twins of items of equipment or building management systems or portions thereof), data lakes, data repositories, documentation records, or various combinations thereof. In some implementations, the data sources 112 include a variety of information pertaining to various sensors, sensor plans, and sensor layouts within various buildings and spaces, such as, for example, efficiency/sustainability data associated with different sensor plans and layouts, cost data (operational and equipment purchase costs) associated with different sensor plans and layouts, air quality data associated with different sensor plans and layouts, BIM data associated with different sensor plans and layouts, audio/visual (A/V) data associated with different sensor plans and layouts, other sensor data associated with different sensor plans and layouts, regulatory data associated with different sensor plans and layouts, and/or procedures including but not limited to installation, operation, configuration, repair, servicing, diagnostics, and/or troubleshooting of various sensors, sensor plans, and sensor layouts.

Various data described below with reference to data sources 112 may be provided in the same or different data elements, and may be updated at various points. The data sources 112 can include or be coupled with items of equipment (e.g., where the items of equipment output data for the data sources 112, such as sensor data, etc.). The data sources 112 can include various online and/or social media sources, such as blog posts or data submitted to applications maintained by entities that manage the buildings. The system 100 can determine relations between data from different sources, such as by using timeseries information and identifiers of the sites or buildings at which items of equipment are present to detect relationships between various different data relating to the items of equipment (e.g., to train the models 104, 116 using both timeseries data (e.g., sensor data; outputs of algorithms or models, etc.) regarding a given item of equipment and freeform natural language reports regarding the given item of equipment).

The data sources 112 can include unstructured data or structured data (e.g., data that is labeled with or assigned to one or more predetermined fields or identifiers). Unstructured data may include data that does not conform to a predetermined format or data that conforms to a plurality of different predetermined formats. For example, the unstructured data may include freeform data that does not conform to any particular format (e.g., freeform text or other freeform data) and/or data that conforms to a combination of different predetermined formats (e.g., a text format, a speech format, an audio format, an image format, a video format, a data file format, etc.). In some embodiments, the unstructured data includes multi-modal data provided by different types of sensory devices (e.g., an audio capture device, a video capture device, an image capture device, a text capture device, a handwriting capture device, etc.). Conversely, structured data may include data that conforms to a predetermined format. In some embodiments, structured data includes data that is labeled with or assigned to one or more predetermined fields or identifiers. For example, the structured data may conform to a structured data format including one or more predetermined fields or locations and one or more predetermined labels or identifiers characterizing the one or more predetermined fields or locations.

Advantageously, using the first model 104 and/or second model 116 to process the data can allow the system 100 to extract useful information from data in a variety of formats, including unstructured/freeform formats, which can allow service technicians to input information in less burdensome formats. The data can be of any of a plurality of formats (e.g., text, speech, audio, image, video, etc.), including multi-modal formats. For example, the data may be received from service technicians or other users (e.g., selected data collecting employees or technicians) in forms such as text (e.g., laptop/desktop or mobile application text entry), audio, and/or video (e.g., dictating findings while capturing video). Any of the various data sources 112 described herein can include any combination of structured or unstructured data in any format or combination of formats, or data that does not conform to any particular format.

The data sources 112 can include engineering data regarding one or more items of equipment. The engineering data can include manuals, such as installation manuals, instruction manuals, or operating procedure guides. The engineering data can include specifications or other information regarding operation of items of equipment. The engineering data can include engineering drawings, CAD files, BIM files, process flow diagrams, refrigeration cycle parameters (e.g., temperatures, pressures), or various other information relating to structures and functions of items of equipment.

In some embodiments, the engineering data indicate various attributes or characteristics of the corresponding items of equipment such as their physical sizes or dimensions (e.g., height, width, depth, etc.), maximum or minimum capacities or operating limits (e.g., minimum or maximum heating capacity, cooling capacity, fluid storage capacity, energy storage capacity, flow rates, thresholds, limits, etc.), required connections to other items of equipment, types of resources produced or consumed by the items of equipment, equipment models that characterize the operating performance of the items of equipment, or any other information that describes or characterizes the items of equipment. For example, the equipment model for a chiller may indicate that the chiller consumes water and electricity as input resources and produces chilled water as an output resource, and may indicate a relationship or function (e.g., an equipment performance curve) between the input resources consumed and output resources produced. Several examples of equipment models for various types of equipment are described in detail in U.S. Pat. No. 10,706,375 granted Jul. 7, 2020, U.S. Pat. No. 11,449,454 granted Sep. 20, 2022, U.S. Pat. No. 9,778,639 granted Oct. 3, 2017, and U.S. Pat. No. 10,372,146 granted Aug. 6, 2019, the entire disclosures of which are incorporated by reference herein. The engineering data can include structured and/or unstructured data of any type or format.

In some implementations, the data sources 112 can include operational data regarding one or more items of equipment. The operational data can represent detected information regarding items of equipment, such as sensor data, logged data, user reports, or technician reports. The operational data can include, for example, service tickets generated responsive to requests for service, work orders, data from digital twin data structures maintained by an entity of the item of equipment, outputs or other information from equipment operation models (e.g., chiller vibration models), or various combinations thereof. Logged data, user reports, service tickets, billing records, time sheets, and various other such data can provide temporal information, such as how long service operations may take, or durations of time between service operations, which can allow the system 100 to predict resources to use for performing service as well as when to request service.

The operational data can include data generated during operation of the building equipment (e.g., measurements from sensors, control signals generated by building equipment, operating states or parameters of the building equipment, etc.) and/or data based on the raw data generated during operation of the building equipment. For example, the operational data can include various types of timeseries data (e.g., timestamped data samples of a given measurement, point, or other data item) such as raw timeseries data generated or observed during operation of the building equipment and/or derived timeseries data generated by processing one or more raw data timeseries. Derived timeseries data may include, for example, fault detection timeseries (e.g., a timeseries that indicates whether a fault is detected at each time step), analytic result timeseries (e.g., a timeseries that indicates the result of a given analytic or metric calculated at each time step), prediction timeseries (e.g., a timeseries of predicted values for future time steps), diagnostic timeseries (e.g., a timeseries of diagnostic results at various time steps), model output timeseries (e.g., a timeseries of values output by a model), or any other type of timeseries that can be created or derived from timeseries data or samples thereof. These and other examples of timeseries data are described in greater detail in U.S. Pat. No. 10,095,756 granted Oct. 9, 2018, the entire disclosure of which is incorporated by reference herein. In some embodiments, the operational data include eventseries data including series of events with corresponding start times and end times. Eventseries are described in greater detail in U.S. Pat. No. 10,417,245 granted Sep. 17, 2019, the entire disclosure of which is incorporated by reference herein.

In some embodiments, the operational data include text data, image data, video data, audio data, or other data that characterize the operation of building equipment. For example, the operational data may include a photograph, image, video, or audio sample of the building equipment taken by a user or technician during operation of the equipment or when performing service or generating a service request. The operational data may include freeform text data entered by a technician or user to record observations of the building equipment or describe problems associated with the building equipment. In some embodiments, the operational data are generated in response to a request for such data by the system 100 (e.g., as part of an automated diagnostic process to determine the root cause of a problem or fault, recorded by a user in response to a prompt for such data from the system 100, etc.). Alternatively or additionally, the operational data may be recorded automatically by one or more sensors (e.g., temperature sensors, optical sensors, indoor air quality (IAQ) sensors, vibration sensors, flow rate sensors, etc.) that are positioned to observe the operation of the building equipment or an effect of the building equipment on a variable state or condition in a building system (e.g., temperature or humidity within a building zone, fluid flow rate within a duct or pipe, vibration of a chiller compressor, air quality within a building zone, etc.). The operational data can include structured and/or unstructured data of any type or format.

The data sources 112 can include, for instance, warranty data. The warranty data can include warranty documents or agreements that indicate conditions under which various entities associated with items of equipment are to provide service, repair, or other actions corresponding to items of equipment, such as actions corresponding to service requests.

The data sources 112 can include service data. The service data can include data from any of various service providers, such as service reports. The service data can indicate service procedures performed, including associated service procedures with initial service requests and/or sensor data related conditions to trigger service and/or sensor data measured during service processes. For example, the service data can include service requests submitted by customers or users of the building equipment (e.g., phone calls, emails, electronic support tickets, etc.) when requesting service or support for building equipment. The service requests can include descriptions of one or more problems associated with the building equipment (e.g., equipment will not start, equipment makes noise when operating, equipment fails to achieve desired setpoint, sensor is providing inaccurate measurements, etc.), photographs of the equipment, or any other type of service request data in any format or combination of formats. The service requests may include information describing the model or type of equipment, the identity of the customer, the location of the equipment, the operating history or service history of the equipment, or any other information that can be used by the system 100 to process the service request and determine an appropriate response.

In some embodiments, the service requests include data provided by a user or customer in response to a guided wizard, a series of prompts from the system 100, and/or an interface provided by an interactive service tool of the system 100. For example, the system 100 may generate and present a user interface that prompts the user to describe a problem associated with the building equipment, upload photos or videos of the building equipment, or otherwise characterize the building equipment or requested service. In some embodiments, the user interface includes a chat interface configured to facilitate conversational interaction with the user (e.g., a chat bot or generative AI interface). The system 100 can be configured to prompt the user for additional information about the building equipment or problem associated with the building equipment and provide dynamic responses to the user based on structured or unstructured data provided by the user via the user interface. The dynamic responses can include suggested resolutions to the problem, potential root causes of the problem, diagnostic steps to be performed to help diagnose the root cause of the problem, or any other type of information that can be provided to the user in response to the service requests.

The service data can include service reports generated by service technicians in connection with performing service on building equipment (e.g., before, during, or after performing service on the building equipment) and may include any observations or notes from the service technicians in any combination of formats. For example, the service data can include a combination of text data entered by a service technician when inspecting building equipment or performing service on the building equipment, photographs or videos recorded by the service technician illustrating the operation of the building equipment, audio/speech data provided by the service technician (e.g., dictating the service provider's observations or actions performed with respect to the building equipment). In some embodiments, the service data indicate one or more actions performed by the service technician when performing service on the building equipment (e.g., sensors) and/or outcome data indicating whether the actions were successful in resolving the problem (e.g., relocating a temperature sensor away from an external window). The service data can include a portion of the operational data, warranty data, or any other type of data described herein which may be relevant to the service requests or service actions performed in response thereto. For example, the service data can include timeseries data recorded prior to a fault occurring in the building equipment, operational data characterizing the operation of the building equipment during testing or service, or operational data characterizing the operation of the building equipment after the service action is performed.

In some embodiments, the service data include metadata associated with the structured or unstructured data elements of the service data. The metadata can include, for example, timestamps indicating times at which various elements of the service data are generated or recorded, location attributes indicating spatial locations (e.g., GPS coordinates, a particular room or zone of a building or campus, etc.) of a service technician or user when the elements of the service data are generated or recorded, device attributes identifying a particular device that generates various elements of the service data, customer attributes identifying a particular customer associated with the service data, or any other type of attribute that can be used to characterize the service data. In some embodiments, the metadata are used by the system 100 to match or associate particular elements of the service data with each other (e.g., a photograph and audio data recorded at or around the same time or when the service technician is in the same location) for use in generating or identifying relationships between various elements of the service data.

In some implementations, the data sources 112 can include parts data, including but not limited to parts usage and sales data. For example, the data sources 112 can indicate various parts associated with installation or repair of items of equipment. The data sources 112 can indicate tools for performing service and/or installing parts.

In some embodiments, the data sources 112 include one or more digital twins, ontological models, relational models, graph data structures, causal relationship models, and/or other types of models that define relationships between various entities in a building system. For example, the data sources 112 may include a digital twin or graph data structure of the building system which includes a plurality of nodes and a plurality of edges. The plurality of nodes may represent various entities in the building system such as systems or devices of building equipment (e.g., chillers, AHUs, security equipment, temperature sensors, a chiller subplant, an airside system, dampers, ducts, sensors, etc.), spaces of the building system (e.g., rooms, floors, building zones, parking lots, outdoor areas, etc.), persons in the building system or associated with the building system (e.g., building occupants, building employees, security or maintenance personnel, service providers for building equipment, etc.), data storage devices, computing devices, data generated by various entities, or any other entity that can be defined in the building system. The plurality of edges may connect the plurality of nodes and define relationships between the entities represented by the plurality of nodes. For example, a first entity in the graph data structure may be a node representing a particular building space (e.g., “zone A”) whereas a second entity in the graph data structure may be a node representing an air handling unit (e.g., “AHU B”) that serves the building space. The nodes representing the first and second entities may be connected by an edge indicating a relationship between the entities. For example, the zone A entity may be connected to the “AHU B” entity via a “served by” relationship indicating that zone A is served by AHU B.

Several examples of digital twins, ontological models, relational models, graph data structures, causal relationship models, and/or other types of models that define relationships between various entities in a building system are described in detail in U.S. Pat. No. 11,108,587 granted Aug. 31, 2021, U.S. Pat. No. 11,164,159 granted Nov. 2, 2021, U.S. Pat. No. 11,275,348 granted Mar. 15, 2022, U.S. patent application Ser. No. 16/673,738 filed Nov. 4, 2019, U.S. patent application Ser. No. 16/685,834 filed Nov. 15, 2019, U.S. patent application Ser. No. 17/728,047 filed Apr. 25, 2022, U.S. patent application Ser. No. 17/134,661 filed Dec. 28, 2020, and U.S. patent application Ser. No. 17/170,533 filed Feb. 8, 2021. The entire disclosures of each of these patents and patent applications are incorporated by reference herein. The system 100 can use these and other types of relational models to determine which equipment have an impact on other equipment or particular building spaces, perform diagnostics to identify potential root causes of problems (e.g., by identifying upstream equipment which could be contributing to the problem or causing the problem), predict the impact of changes to a given item of building equipment on the other equipment or spaces served by the given item of equipment (e.g., by identifying downstream equipment or spaces impacted by a given item of building equipment), or otherwise derive insights that can be used by the system 100 to recommend various actions to perform (e.g., equipment service recommendations, diagnostic processes to run, etc.) and/or predict the consequences of various courses of action on the related equipment and spaces.

In some embodiments, the data sources 112 may include a predictive cost model configured to predict various types of cost associated with operation of the building equipment. For example, the predictive cost model can be used by system 100 to predict operating cost, maintenance cost, equipment purchase or replacement cost (e.g., capital cost), equipment degradation cost, cost of purchasing carbon offset credits, rate of return (e.g., on an investment in energy-efficient equipment), payback period, and/or any of the other sources of monetary cost or cost-related metrics described in U.S. patent application Ser. No. 15/895,836 filed Feb. 13, 2018, U.S. patent application Ser. No. 16/418,686 filed May 21, 2019, U.S. patent application Ser. No. 16/438,961 filed Jun. 12, 2019, U.S. patent application Ser. No. 16/449,198 filed Jun. 21, 2019, U.S. patent application Ser. No. 16/457,314 filed Jun. 28, 2019, U.S. patent application Ser. No. 16/697,099 filed Nov. 26, 2019, U.S. patent application Ser. No. 16/687,571 filed Nov. 18, 2019, U.S. patent application Ser. No. 16/518,548 filed Jul. 22, 2019, U.S. patent application Ser. No. 16/899,220 filed Jun. 11, 2020, U.S. patent application Ser. No. 16/943,781 filed Jul. 30, 2020, and/or U.S. patent application Ser. No. 17/017,028 filed Sep. 10, 2020. The entire disclosures of each of these patent applications are incorporated by reference herein. The system 100 can use the predictive cost models to predict the cost that will result from various actions that could be performed by the system 100 or by service providers (e.g., purchasing and installing new equipment, performing maintenance on the building equipment, energy waste resulting from allowing a fault to remain unrepaired, switching to a new control strategy, etc.) to provide insight into the consequences of various courses of action that can be recommended by the system 100.

The data sources 112 may include one or more thermodynamic models configured to predict one or more thermodynamic properties or states of a building space or fluid flow (e.g., temperature, humidity, pressure, enthalpy, etc.) as a result of operation of the building equipment. For example, the thermodynamic models can be configured to predict the temperature, humidity, or air quality of a building space that will occur if the building equipment are operated according to a given control strategy. The thermodynamic models can be configured to predict the temperature, enthalpy, pressure, or other thermodynamic state of a fluid (e.g., water, air, refrigerant) in a duct or pipe, received as an input to the building equipment, or provided as an output from the building equipment. Several examples of thermodynamic models that can be used to predict various thermodynamic properties or states of a building space or fluid flow are described in greater detail in U.S. Pat. No. 11,067,955 granted Jul. 20, 2021, U.S. Pat. No. 10,761,547 granted Sep. 1, 2020, and U.S. Pat. No. 9,696,073 granted Jul. 4, 2017, the entire disclosures of which are incorporated by reference herein. The system 100 can use the thermodynamic models to predict the temperature, humidity, or other thermodynamic states that will occur at various locations within the building as a result of different actions that could be performed by the system 100 or by service providers (e.g., purchasing and installing new equipment, performing maintenance on the building equipment, switching to a new control strategy, etc.) to confirm that the recommended set of actions or control strategies will result in comfortable building conditions and within operating limits or constraints for the building equipment or spaces of the building.

The system 100 can include, with the data of the data sources 112, labels to facilitate cross-reference between items of data that may relate to common items of equipment, sites, service technicians, customers, or various combinations thereof. For example, data from disparate sources may be labeled with time data, which can allow the system 100 (e.g., by configuring the models 104, 116) to increase a likelihood of associating information from the disparate sources due to the information being detected or recorded (e.g., as service reports) at the same time or near in time.

For example, the data sources 112 can include data that can be particular to specific or similar items of equipment, buildings, equipment configurations, environmental states, or various combinations thereof. In some implementations, the data includes labels or identifiers of such information, such as to indicate locations, weather conditions, timing information, efficiency or power consumption information, uses of the items of equipment or the buildings or sites at which the items of equipment are present, etc. This can enable the models 104, 116 to detect patterns of usage (e.g., spikes; troughs; seasonal or other temporal patterns) or other information that may be useful for determining efficiencies and other characteristics of various sensor plans and layouts, such as to allow the models 104, 116 to be trained using information indicative of a variety of sensor plans and layouts and their corresponding characteristics to autonomously generate a variety of proposed sensor plans and layouts for new spaces in new buildings.

### Model Configuration

Referring further to FIG. 1, the model updater 108 can perform various machine learning model configuration/training operations to determine the second models 116 using the data from the data sources 112. For example, the model updater 108 can perform various updating, optimization, retraining, reconfiguration, fine-tuning, or transfer learning operations, or various combinations thereof, to determine the second models 116. The model updater 108 can configure the second models 116, using the data sources 112, to generate outputs (e.g., completions) in response to receiving inputs (e.g., prompts), where the inputs and outputs can be analogous to data of the data sources 112.

For example, the model updater 108 can identify one or more parameters (e.g., weights and/or biases) of one or more layers of the first model 104, and maintain (e.g., freeze, maintain as the identified values while updating) the values of the one or more parameters of the one or more layers. In some implementations, the model updater 108 can modify the one or more layers, such as to add, remove, or change an output layer of the one or more layers, or to not maintain the values of the one or more parameters. The model updater 108 can select at least a subset of the identified one or parameters to maintain according to various criteria, such as user input or other instructions indicative of an extent to which the first model 104 is to be modified to determine the second model 116. In some implementations, the model updater 108 can modify the first model 104 so that an output layer of the first model 104 corresponds to output to be determined for applications 120.

Responsive to selecting the one or more parameters to maintain, the model updater 108 can apply, as input to the second model 116 (e.g., to a candidate second model 116, such as the modified first model 104, such as the first model 104 having the identified parameters maintained as the identified values), training data from the data sources 112. For example, the model updater 108 can apply the training data as input to the second model 116 to cause the second model 116 to generate one or more candidate outputs.

The model updater 108 can evaluate a convergence condition to modify the candidate second model 116 based at least on the one or more candidate outputs and the training data applied as input to the candidate second model 116. For example, the model updater 108 can evaluate an objective function of the convergence condition, such as a loss function (e.g., L1 loss, L2 loss, root mean square error, cross-entropy or log loss, etc.) based on the one or more candidate outputs and the training data; this evaluation can indicate how closely the candidate outputs generated by the candidate second model 116 correspond to the ground truth represented by the training data. The model updater 108 can use any of a variety of optimization algorithms (e.g., gradient descent, stochastic descent, Adam optimization, etc.) to modify one or more parameters (e.g., weights or biases of the layer(s) of the candidate second model 116 that are not frozen) of the candidate second model 116 according to the evaluation of the objective function. In some implementations, the model updater 108 can use various hyperparameters to evaluate the convergence condition and/or perform the configuration of the candidate second model 116 to determine the second model 116, including but not limited to hyperparameters such as learning rates, numbers of iterations or epochs of training, etc.

As described further herein with respect to applications 120, in some implementations, the model updater 108 can select the training data from the data of the data sources 112 to apply as the input based at least on a particular application of the plurality of applications 120 for which the second model 116 is to be used for. For example, the model updater 108 can select data from the BIM data source 112 for the visualization generator application 120, or select various combinations of data from the data sources 112 (e.g., cost data, regulatory data, and efficiency/sustainability data) for either of the sensor plan or sensor layout generator applications 120. The model updater 108 can apply various combinations of data from various data sources 112 to facilitate configuring the second model 116 for one or more applications 120.

In some implementations, the system 100 can perform at least one of conditioning, classifier-based guidance, or classifier-free guidance to configure the second model 116 using the data from the data sources 112. For example, the system 100 can use classifiers associated with the data, such as identifiers of the item of equipment, a type of the item of equipment, a type of entity operating the item of equipment, a site at which the item of equipment is provided, or a history of issues at the site, to condition the training of the second model 116. For example, the system 100 combine (e.g., concatenate) various such classifiers with the data for inputting to the second model 116 during training, for at least a subset of the data used to configure the second model 116, which can enable the second model 116 to be responsive to analogous information for runtime/inference time operations.

In some embodiments, the model updater 108 trains the second model using a plurality of unstructured service reports corresponding to a plurality of service requests handled by technicians for servicing building equipment. The unstructured service reports may include unstructured data which does not conform to a predetermined format or may conform to a plurality of different predetermined formats. The unstructured service reports can include any of the types of structured or unstructured data previously described (e.g., text data, speech data, audio data, image data, video data, freeform data, etc.). For example, in some embodiments, the unstructured service reports can be or include service call information (e.g., transcripts, shared images, shared videos, audio information, etc.) pertaining to the functioning or malfunctioning of various building equipment (e.g., sensors) and corresponding service actions taken to resolve functionality issues (e.g., accuracy issues) associated with the building equipment.

In some embodiments, the model updater 108 can train the second model 116 using outcome data in combination with the unstructured service reports from service technicians. The unstructured service reports may indicate various actions performed by the service technicians when performing service on the building equipment, whereas the outcome data may indicate outcomes of the various actions. For example, the outcome data may indicate whether the problems associated with the building equipment were resolved after performing the various actions. The model updater 108 can use this combination of service report data and outcome data to identify patterns or correlations between the particular actions performed and their respective outcomes. Similarly, the model updater 108 can train the second model 116 to identify new correlations and/or patterns between the unstructured data of the unstructured service reports and the additional data from any of the additional data sources described herein. Accordingly, when a new service request or service report is provided as an input to the second model 116, the second model 116 can be used to identify new correlations and/or patterns between unstructured data of the new service report and the additional data from the additional data sources.

In some embodiments, the model updater 108 can train the second model 116 using both the unstructured data from the unstructured service reports and additional data gathered by the model updater 108. For example, the model updater 108 (or another component of the system 100) can identify particular entities of the building system indicated by the unstructured service reports (e.g., particular devices of building equipment, spaces of the building system, data entities, etc.) and retrieve additional data relevant to the identified entities. In some embodiments, the model updater 108 can traverse (e.g., use, evaluate, travel along, etc.) an ontological model of the building system to identify one or more other systems or devices of building equipment, spaces of the building system, or other entities of the building system related to the particular entities indicated in the unstructured service reports. The model updater 108 can train the second model 116 using additional data associated with the identified one or more other items of building equipment, spaces of the building system, or other entities of the building system in combination with the unstructured data of the unstructured service reports to configure the second model 116.

In some embodiments, the ontological model of the building system includes a digital twin of a building system. The digital twin may include a plurality of nodes representing the building equipment, the other systems or devices of building equipment, the spaces of the building system, or the other entities of the building system. The digital twin may also include a plurality of edges connecting the plurality of nodes and defining relationships between the building equipment, the other systems or devices of building equipment, the spaces of the building system, or the other entities of the building system represented by the nodes. The model updater 108 can use the relationships defined by the digital twin to determine other entities related to the entities identified in the unstructured service reports and gather additional data associated with the identified entities.

In some embodiments, the model updater 108 can train the second model 116 using training data associated with one or more similar items of building equipment, buildings, customers, or other entities based on the unstructured service reports. For example, the model updater 108 can use various characteristics of the buildings, customers, or other entities identified in the unstructured service reports to identify other buildings, customers, or other entities that have similar characteristics (e.g., same or similar model of a chiller, same or similar geographic location of a building, same or similar weather patterns, etc.). The model updater 108 can gather additional training data associated with the identified buildings, customers, or other entities to expand the set of training data used to train the second model 116.

In some embodiments, the model updater 108 can train the second model 116 using a set of structured reports. The structured reports can be generated from the unstructured service reports (e.g., using the second model 116) or otherwise provided as an input to the model updater 108. The structured reports can be service reports (i.e., structured service reports) or other types of reports (e.g., energy consumption reports, fault reports, equipment performance reports, etc.). The model updater 108 can use the structured reports in combination with the unstructured service reports to configure the second model 116.

In some embodiments, the model updater 108 trains the second model 116 using additional data generated by one or more other models separate from the second model 116. The other models may include, for example, a thermodynamic model configured to predict one or more thermodynamic properties or states of a building space or fluid flow as a result of operation of the building equipment, an energy model configured to predict consumption or generation of one or more energy resources as a result of the operation of the building equipment, a sustainability model configured to predict one or more sustainability metrics as a result of the operation of the building equipment, an occupant comfort model configured to predict occupant comfort as a result of the operation of the building equipment, an infection risk model configured to predict infection risk in one or more building spaces as a result of the operation of the building equipment, an air quality model configured to predict air quality in one or more building spaces as a result of the operation of the building equipment, and/or any of the other types of models described throughout the present disclosure or the patents and patent applications incorporated by reference herein.

In some embodiments, the model updater 108 uses the additional data generated by the other models in combination with the unstructured data of the unstructured service reports to configure the trained second model 116. The additional data generated by the other models can also or alternatively be used by the applications 120 in combination with an output of the second model 116 to select an action to perform. For example, the output of the trained second model 116 (e.g., a recommended action to perform) can be provided as an input to the other models to predict a consequence of the recommended action on energy consumption, occupant comfort, air quality, sustainability, infection risk, or any other variable state or condition predicted or modeled by the other models. The output of the other models can then be used by the system 100 to evaluate the consequences of the recommended action (e.g., score the recommended action relative to other recommended actions based on the consequences) and/or provide a user interface that informs the user of the consequences when presenting the recommended actions for user consideration.

In some embodiments, the output of the trained second model 116 is provided as an input to the other models and used to generate additional training data as an output of the other models. The additional training data can then be used to further train or refine the second model 116. For example, the output of the other models may indicate expected consequences or outcomes of the actions recommended by the second model 116. The expected consequences or outcomes can then be used as feedback to the model updater 108 to adjust the second model 116 (e.g., by reinforcing actions that lead to positive consequences, punishing actions that lead to negative consequences, etc.).

In some embodiments, the model updater 108 trains the second model 116 to automatically generate a structured service report in a predetermined format for delivery to a customer associated with the building equipment. The model updater 108 may receive training data including a plurality of first unstructured service reports corresponding to a plurality of first service requests handled by technicians for servicing building equipment. The plurality of first unstructured service reports may include unstructured data not conforming to a predetermined format or conforming to a plurality of different predetermined formats. The model updater 108 may train the second model 116 using the plurality of unstructured service reports. When a new unstructured service report is received, the second model 116 can then be used to generate a new structured service report which includes additional content generated by the second model 116 and not provided within the new unstructured service report.

In some embodiments, the training data used by the model updater 108 to train the second model 116 includes one or more structured service reports conforming to a predetermined format (e.g., a structured data format, a template for a particular customer or type of equipment, etc.) and including one or more predefined form sections or fields. After the second model 116 is trained, the second model 116 can then be used (e.g., by the document writer application 120 described below) to automatically populate the one or more predefined form sections or fields with structured data elements generated from unstructured data of the unstructured service report.

### Applications

Referring further to FIG. 1, the system 100 can use outputs of the one or more second models 116 to implement one or more applications 120. For example, the second models 116, having been configured using data from the data sources 112, can be capable of precisely generating outputs that represent useful, timely, and/or real-time information for the applications 120. In some implementations, each application 120 is coupled with a corresponding second model 116 that is specifically configured to generate outputs for use by the application 120. Various applications 120 can be coupled with one another, such as to provide outputs from a first application 120 as inputs or portions of inputs to a second application 120.

The applications 120 can include any of a variety of desktop, web-based/browser-based, or mobile applications. For example, the applications 120 can be implemented by enterprise management software systems, employee or other user applications (e.g., applications that relate to BMS functionality such as temperature control, user preferences, conference room scheduling, etc.), equipment portals that provide data regarding items of equipment, or various combinations thereof. The applications 120 can include user interfaces, wizards, checklists, conversational interfaces, chatbots, configuration tools, or various combinations thereof. The applications 120 can receive an input, such as a prompt (e.g., from a user), provide the prompt to the second model 116 to cause the second model 116 to generate an output, such as a completion in response to the prompt, and present an indication of the output.

The applications 120 can receive inputs and/or present outputs in any of a variety of presentation modalities, such as text, speech, audio, image, and/or video modalities. For example, the applications 120 can receive unstructured or freeform inputs from a user, such as a site planner or other equipment or sensor installation manager, and generate reports in a standardized format, such as a customer-specific format. This can allow, for example, a user (e.g., a site planner or other equipment or sensor installation manager) to automatically, and flexibly, have a variety of differing sensor plans and sensor layouts achieving differing goals and meeting differing requirements and/or other related information generated without requiring strict input by the user or requiring the user to manually sit down and write reports; to receive inputs as dictations in order to generate the sensor plans/layouts and/or other related information; to receive inputs in any form or a variety of forms, and use the second model 116 (which can be trained to cross-reference metadata in different portions of inputs and relate together data elements) to generate the sensor plans/layouts and/or other related information (e.g., the second model 116, having been configured with data that includes time information, can use timestamps of input from dictation and timestamps of when an image is taken, and place the image in the report in a target position or label based on time correlation).

In some embodiments, the applications 120 can be configured to couple or link the information provided in unstructured service reports or service request with other input or output data sources, such as any of the data sources 112 described herein. For example, the applications 120 can receive unstructured service data corresponding to one or more service requests handled by technicians for servicing building equipment. The unstructured service data can be included in unstructured service reports generated by the technicians and/or the corresponding service requests. The unstructured service data may include one or more unstructured data elements not conforming to a predetermined format or conforming to a plurality of different predetermined formats (e.g., a text format, a speech format, an audio format, an image format, a video format, a data file format, etc.). The applications 120 can use the unstructured service data and/or other attributes of the service reports or the service requests to identify a particular item of building equipment, a building space, or other entity associated with the unstructured service data (e.g., a particular device or space identified as requiring service). In various embodiments, the applications 120 can use the second model 116 or a different model, system, or device to process the unstructured service data and identify a particular system or device of the building equipment associated with the unstructured service data.

The applications 120 can automatically identify one or more additional data sources which are relevant to the identified item of building equipment, space, or other entity. For example, the applications 120 can use a relational model of the building system, output from a diagnostic model, or other information to identify related items of building equipment, spaces, data sources, or other entities of the building system. The applications 120 can then retrieve additional data associated with the building equipment, space, or other entity from one or more additional data sources separate from the unstructured service data. The applications 120 can use the unstructured service data and the additional data from the additional data sources to generate a structured data output using the second model 116. The structured data output may include one or more structured data elements based on the unstructured service data and the additional data from the one or more additional data sources.

The additional data sources which can be coupled or linked to the information in the unstructured service reports and/or service requests can include any of the data sources 112 described herein. For example, the additional data sources can include engineering data, operational data, sensor data, timeseries data, warranty data, parts data, outcome data, and/or model output data. The model output data can include data generated by any of a variety of models such as a thermodynamic model configured to predict one or more thermodynamic properties or states of a building space or fluid flow as a result of operation of the building equipment, an energy model configured to predict consumption or generation of one or more energy resources as a result of the operation of the building equipment, a sustainability model configured to predict one or more sustainability metrics as a result of the operation of the building equipment, an occupant comfort model configured to predict occupant comfort as a result of the operation of the building equipment, an infection risk model configured to predict infection risk in one or more building spaces as a result of the operation of the building equipment, and/or an air quality model configured to predict air quality in one or more building spaces as a result of the operation of the building equipment.

In some embodiments, the applications 120 can retrieve the additional data by traversing an ontological model of the building system to identify one or more other systems or devices of building equipment, spaces of the building system, or other entities of the building system related to the building equipment. The applications 120 can then retrieve the additional data associated with the identified one or more other systems or devices of building equipment, spaces of the building system, or other entities of the building system. In some embodiments, the ontological model of the building system includes a digital twin of a building system. The digital twin may include a plurality of nodes representing the building equipment, the other systems or devices of building equipment, the spaces of the building system, or the other entities of the building system. The digital twin may further include a plurality of edges connecting the plurality of nodes and defining relationships between the building equipment, the other systems or devices of building equipment, the spaces of the building system, or the other entities of the building system represented by the nodes.

In some embodiments, the applications 120 can retrieve the additional data by identifying one or more similar items of building equipment, buildings, customers, or other entities related to the building equipment. The applications can retrieve the additional data associated with the identified one or more similar items of building equipment, buildings, customers. In some embodiments, the additional data include internet data obtained from one or more internet data sources such as a website, a blog post, a social media source, or a calendar. In some embodiments, the additional data include application data obtained from one or more applications installed on one or more user devices. The application data may include user comfort feedback for one or more building spaces affected by operation of the building equipment. In various embodiments, the additional data can include additional unstructured data not conforming to a predetermined format or conforming to a plurality of different predetermined formats and/or structured data including one or more predetermined fields or locations and one or more predetermined labels or identifiers characterizing the one or more predetermined fields or locations.

In some embodiments, the applications 120 can retrieve the additional data by cross-referencing metadata associated with the unstructured service data and the additional data to determine whether the unstructured service data and the additional data are related. If the unstructured service data and the additional data are related, the applications 120 can retrieve the additional data from the corresponding additional data sources. In various embodiments, the metadata can include timestamps indicating times associated with the unstructured service data and the additional data and/or location attributes indicating spatial locations in a building or campus associated with the unstructured service data and the additional data. Determining that the two unstructured service data and the additional data are related may include comparing the timestamps and/or the location attributes.

In some implementations, the applications 120 include at least one virtual assistant (e.g., virtual assistance for site planners or other equipment or sensor installation managers) application 120. The virtual assistant application can provide an interface between users (e.g., site planner or other equipment or sensor installation managers) and the various other applications 120 (e.g., the sensor plan/layout generator applications, the visualization generator application, the performance index generator application) to provide various services to support the users, such as allowing the users to collect various information pertaining to a given space in a building, generating and providing proposed sensor layouts, allowing users to provide feedback on the proposed sensor plans/layouts, and modifying and providing the modified proposed sensor plans/layouts to the user. The virtual assistant application can receive information regarding a given space within a building for which a sensor plan/layout is request in a variety of ways, such as, for example, sensor data, text descriptions, camera images, etc. and process the received information using the second model 116 to generate corresponding responses.

For example, the virtual assistant application 120 can be implemented in a UI/UX wizard configuration, such as to provide a sequence of requests for information from the user (the sequence may include requests that are at least one of predetermined or dynamically generated responsive to inputs from the user for previous requests). For example, the virtual assistant application 120 can provide one or more requests for users such as site planners, other equipment or sensor installation managers, or other occupants generally, and provide the received responses to at least one of the second model 116. The virtual assistant application 120 can use requests for information such as for unstructured text by which the user describes characteristics of the item of equipment relating to the issue; answers expected to correspond to different scenarios indicative of the issue; and/or image and/or video input (e.g., images of problems, equipment, spaces, etc. that can provide more context around the issue and/or configurations).

The virtual assistant application 120 can include a plurality of applications 120 (e.g., variations of interfaces or customizations of interfaces) for a plurality of respective user types. For example, the virtual assistant application 120 can include a first application 120 for a customer user, and a second application 120 for a site planner or other equipment or sensor installation manager. The virtual assistant applications 120 can allow for updating and other communications between the first and second applications 120 as well as the second model 116. Using one or more of the first application 120 and the second application 120, the system 100 can manage continuous/real-time conversations for one or more users, and evaluate the users' engagement with the information provided (e.g., did the user, customer, service technician, etc., follow the provided steps for a given task, did the user discontinue providing inputs to the virtual assistant application 120, etc.), such as to enable the system 100 to update the information generated by the second model 116 for the virtual assistant application 120 according to the engagement. In some implementations, the system 100 can use the second model 116 to detect sentiment of the user of the virtual assistant application 120, and update the second model 116 according to the detected sentiment, such as to improve the experience provided by the virtual assistant application 120.

The applications 120 can include sensor plan/layout generator application 120. The sensor plan/layout generator application 120 can facilitate autonomously determining goals and requirements for a given space, proposing sensor plans and/or sensor layouts, accepting feedback on proposed sensor plans and/or sensor layouts, and providing modified proposed sensor plans and/or sensor layouts.

The applications 120 can include, in some implementations, at least one visualization generator application 120. The visualization generator application 120 can receive inputs including, for example, BIM data, video data, etc., as well as one or more proposed sensor plan/layouts from the sensor plan/layout generator application 120, and autonomously generate one or more visualizations of the proposed sensor plan/layouts within the building. For example, the one or more visualizations may include images, videos, graphical models, or other suitable visualizations for displaying on a screen, in a metaverse context, in a graphical model viewer, in a virtual reality context, and/or in an augmented reality context to a user.

The applications 120 can further include a performance index generator application 120. The performance index generator application 120 can receive inputs such as a various information about a given space within a building, and provide the inputs to the second model 116 to cause the second model 116 to generate outputs for presenting a sensor performance index for a current sensor layout, as well as a number of proposed sensor plans/layouts generated by the sensor plan/layout generator application 120.

### Feedback Training

Referring further to FIG. 1, the system 100 can include at least one feedback trainer 128 coupled with at least one feedback repository 124. The system 100 can use the feedback trainer 128 to increase the precision and/or accuracy of the outputs generated by the second models 116 according to feedback provided by users of the system 100 and/or the applications 120.

The feedback repository 124 can include feedback received from users regarding output presented by the applications 120. For example, for at least a subset of outputs presented by the applications 120, the applications 120 can present one or more user input elements for receiving feedback regarding the outputs. The user input elements can include, for example, indications of binary feedback regarding the outputs (e.g., good/bad feedback; feedback indicating the outputs do or do not meet the user's criteria, such as criteria regarding technical accuracy or precision); indications of multiple levels of feedback (e.g., scoring the outputs on a predetermined scale, such as a 1-5 scale or 1-10 scale); freeform feedback (e.g., text or audio feedback); or various combinations thereof.

The system 100 can store and/or maintain feedback in the feedback repository 124. In some implementations, the system 100 stores the feedback with one or more data elements associated with the feedback, including but not limited to the outputs for which the feedback was received, the second model(s) 116 used to generate the outputs, and/or input information used by the second models 116 to generate the outputs (e.g., service request information; information captured by the user regarding the item of equipment).

The feedback trainer 128 can update the one or more second models 116 using the feedback. The feedback trainer 128 can be similar to the model updater 108. In some implementations, the feedback trainer 128 is implemented by the model updater 108; for example, the model updater 108 can include or be coupled with the feedback trainer 128. The feedback trainer 128 can perform various configuration operations (e.g., retraining, fine-tuning, transfer learning, etc.) on the second models 116 using the feedback from the feedback repository 124. In some implementations, the feedback trainer 128 identifies one or more first parameters of the second model 116 to maintain as having predetermined values (e.g., freeze the weights and/or biases of one or more first layers of the second model 116), and performs a training process, such as a fine tuning process, to configure parameters of one or more second parameters of the second model 116 using the feedback (e.g., one or more second layers of the second model 116, such as output layers or output heads of the second model 116).

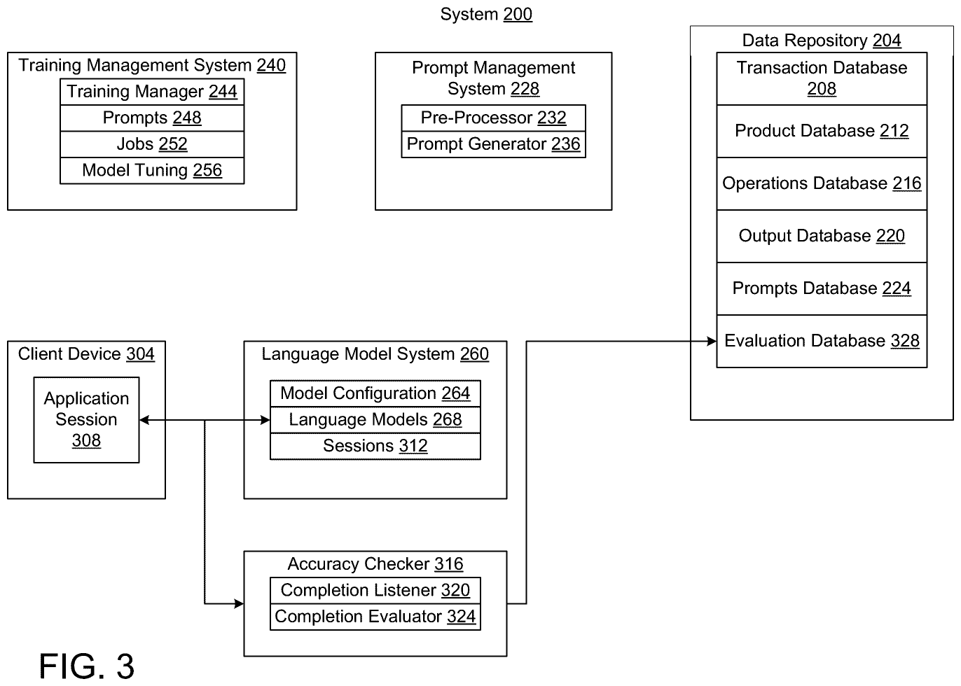

In some implementations, the system 100 may not include and/or use the model updater 108 (or the feedback trainer 128) to determine the second models 116. For example, the system 100 can include or be coupled with an output processor (e.g., an output processor similar or identical to accuracy checker 316 described with reference to FIG. 3) that can evaluate and/or modify outputs from the first model 104 prior to operation of applications 120, including to perform any of various post-processing operations on the output from the first model 104. For example, the output processor can compare outputs of the first model 104 with data from data sources 112 to validate the outputs of the first model 104 and/or modify the outputs of the first model 104 (or output an error) responsive to the outputs not satisfying a validation condition.

In some embodiments, the feedback trainer 128 receives feedback indicating a quality of one or more outputs of the second model 116 and uses the feedback in combination with the set of unstructured service reports to configure or update the trained second model 116. The feedback can include, for example, binary feedback associating the one or more outputs of the second model 116 with a predetermined binary category (e.g., acceptable/unacceptable, good/bad, problem resolved/unresolved, etc.), technical feedback indicating whether the one or more outputs of the second model 116 satisfy technical accuracy or precision criteria (e.g., whether the outputs conform to a predetermined format, meet customer requirements, or are accurate to the technical characteristics of the building system or equipment), score feedback assigning a score to the one or more outputs of the second model 116 on a predetermined scale (e.g., a numerical score within a range of 1-10, a scale including three or more categories such as good, acceptable, bad, etc.), and/or freeform feedback from one or more subject matter experts (e.g., freeform text describing problems or errors with the outputs of the second model 116).

In some embodiments, the feedback indicates a quality of the structured service report generated by the document writer application 120. The feedback trainer 128 can receive the feedback indicating the quality of the structured service report and configure or update the second model 116 using the feedback.

### Connected Machine Learning Models

Referring further to FIG. 1, the second model 116 can be coupled with one or more third models, functions, or algorithms for training/configuration and/or runtime operations. The third models can include, for example and without limitation, any of various models relating to items of equipment, such as energy usage models, sustainability models, carbon models, air quality models, or occupant comfort models. For example, the second model 116 can be used to process unstructured information regarding items of equipment into predefined template formats compatible with various third models, such that outputs of the second model 116 can be provided as inputs to the third models; this can allow more accurate training of the third models, more training data to be generated for the third models, and/or more data available for use by the third models. The second model 116 can receive inputs from one or more third models, which can provide greater data to the second model 116 for processing.

### Automated Goal-Based Sensor Plan Generation

The system 100 can be used to automate operations for goal-based sensor plan generation. For example, the system 100 can use at least one of the first model 104 or the second model 116 to determine, based on received data pertaining to a given space within a building, one or more goals and/or regulatory requirements for the space, generate one or more proposed sensor plans/layouts for the space based on the received data and determined goal(s), and provide the proposed sensor plans/layouts to a user for review. In some implementations, the system 100 can also be utilized to received feedback from a user regarding proposed sensor plans/layouts, autonomously modify the proposed sensor plans/layouts, and provide the modified proposed sensor plans/layouts to the user for review.

### II. System Architectures for Generative AI Applications for Building Management System and Goal-Based Sensor Plan/Layout Generation

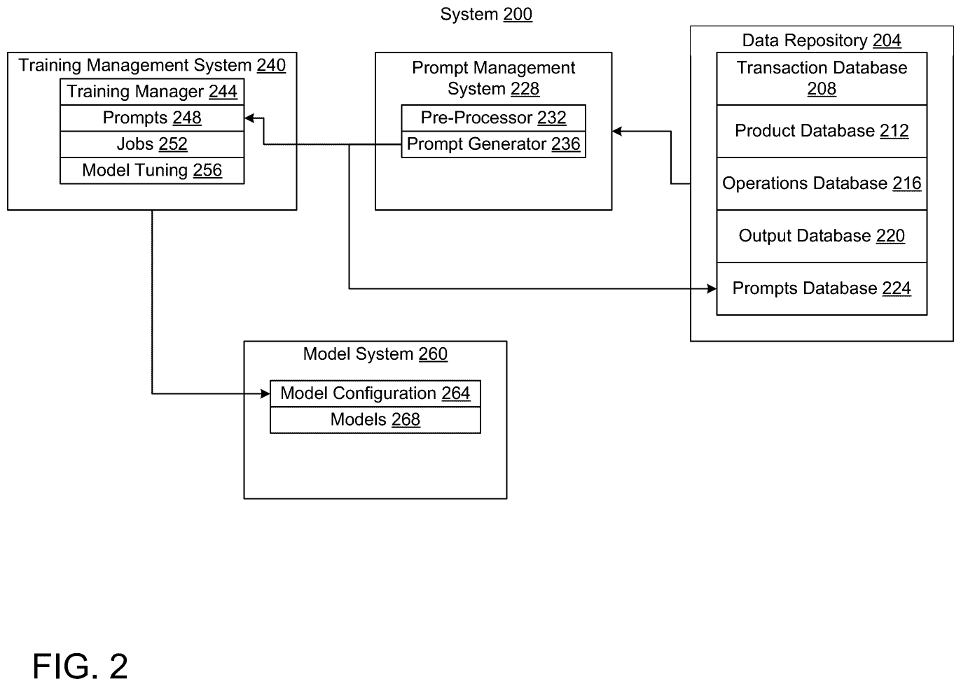

FIG. 2 depicts an example of a system 200. The system 200 can include one or more components or features of the system 100, such as any one or more of the first model 104, data sources 112, second model 116, applications 120, feedback repository 124, and/or feedback trainer 128. The system 200 can perform specific operations to enable generative AI applications for building managements systems and goal-based sensor plan/layout generation, such as various manners of processing input data into training data (e.g., tokenizing input data; forming input data into prompts and/or completions), and managing training and other machine learning model configuration processes. Various components of the system 200 can be implemented using one or more computer systems, which may be provided on the same or different processors (e.g., processors communicatively coupled via wired and/or wireless connections).

The system 200 can include at least one data repository 204, which can be similar to the data sources 112 described with reference to FIG. 1. For example, the data repository 204 can include a transaction database 208, which can be similar or identical to one or more of warranty data or service data of data sources 112. For example, the transaction database 208 can include data such as parts used for service transactions; sales data indicating various service transactions or other transactions regarding items of equipment; warranty and/or claims data regarding items of equipment; and service data.

The data repository 204 can include a product database 212. The product database 212 can include, for example, data regarding products available from various vendors, specifications or parameters regarding products (e.g., data pertaining to sensors similar to the sensor data source 112), indications of products used for various service operations, regulatory data pertaining to various products (e.g., similar to the regulatory data source 112), efficiency/sustainability information associated with specific products, cost data associated with products, and/or any other pertinent information relating to products or equipment within a building. The product database 212 can include data such as events or alarms associated with products; logs of product operation; and/or time series data regarding product operation, such as longitudinal data values of operation of products and/or building equipment.

The data repository 204 can include an operations database 216. For example, the operations database 216 can include data such as manuals regarding parts, products, and/or items of equipment; customer service data; reports, such as operation or service logs, efficiencies; audio or visual data pertaining to the operations within a building, air quality data information pertaining to a building, efficiency/sustainability data associated with a building or spaces within a building, and/or any other pertinent information relating to a building's operations.

In some implementations, the data repository 204 can include an output database 220, which can include data of outputs that may be generated by various machine learning models and/or algorithms. For example, the output database 220 can include values of pre-calculated predictions and/or insights, such as parameters regarding operation items of equipment, such as setpoints, changes in setpoints, flow rates, control schemes, identifications of error conditions, predicted measurement readings, or various combinations thereof.

As depicted in FIG. 2, the system 200 can include a prompt management system 228. The prompt management system 228 can include one or more rules, heuristics, logic, policies, algorithms, functions, machine learning models, neural networks, scripts, or various combinations thereof to perform operations including processing data from data repository 204 into training data for configuring various machine learning models. For example, the prompt management system 228 can retrieve and/or receive data from the data repository 204, and determine training data elements that include examples of input and outputs for generation by machine learning models, such as a training data element that includes a prompt and a completion corresponding to the prompt, based on the data from the data repository 204.

In some implementations, the prompt management system 228 includes a pre-processor 232. The pre-processor 232 can perform various operations to prepare the data from the data repository 204 for prompt generation. For example, the pre-processor 232 can perform any of various filtering, compression, tokenizing, or combining (e.g., combining data from various databases of the data repository 204) operations.

The prompt management system 228 can include a prompt generator 236. The prompt generator 236 can generate, from data of the data repository 204, one or more training data elements that include a prompt and a completion corresponding to the prompt. In some implementations, the prompt generator 236 receives user input indicative of prompt and completion portions of data. For example, the user input can indicate template portions representing prompts of structured data, such as predefined fields or forms of documents, and corresponding completions provided for the documents. The user input can assign prompts to unstructured data. In some implementations, the prompt generator 236 automatically determines prompts and completions from data of the data repository 204, such as by using any of various natural language processing algorithms to detect prompts and completions from data. In some implementations, the system 200 does not identify distinct prompts and completions from data of the data repository 204.

Referring further to FIG. 2, the system 200 can include a training management system 240. The training management system 240 can include one or more rules, heuristics, logic, policies, algorithms, functions, machine learning models, neural networks, scripts, or various combinations thereof to perform operations including controlling training of machine learning models, including performing fine tuning and/or transfer learning operations.

The training management system 240 can include a training manager 244. The training manager 244 can incorporate features of at least one of the model updater 108 or the feedback trainer 128 described with reference to FIG. 1. For example, the training manager 244 can provide training data including a plurality of training data elements (e.g., prompts and corresponding completions) to the model system 260 as described further herein to facilitate training machine learning models.

In some implementations, the training management system 240 includes a prompts database 248. For example, the training management system 240 can store one or more training data elements from the prompt management system 228, such as to facilitate asynchronous and/or batched training processes.

The training manager 244 can control the training of machine learning models using information or instructions maintained in a model tuning database 256. For example, the training manager 244 can store, in the model tuning database 256, various parameters or hyperparameters for models and/or model training.

In some implementations, the training manager 244 stores a record of training operations in a jobs database 252. For example, the training manager 244 can maintain data such as a queue of training jobs, parameters or hyperparameters to be used for training jobs, or information regarding performance of training.

Referring further to FIG. 2, the system 200 can include at least one model system 260 (e.g., one or more language model systems). The model system 260 can include one or more rules, heuristics, logic, policies, algorithms, functions, machine learning models, neural networks, scripts, or various combinations thereof to perform operations including configuring one or more machine learning models 268 based on instructions from the training management system 240. In some implementations, the training management system 240 implements the model system 260. In some implementations, the training management system 240 can access the model system 260 using one or more APIs, such as to provide training data and/or instructions for configuring machine learning models 268 via the one or more APIs. The model system 260 can operate as a service layer for configuring the machine learning models 268 responsive to instructions from the training management system 240. The machine learning models 268 can be or include the first model 104 and/or second model 116 described with reference to FIG. 1.

The model system 260 can include a model configuration processor 264. The model configuration processor 264 can incorporate features of the model updater 108 and/or the feedback trainer 128 described with reference to FIG. 1. For example, the model configuration processor 264 can apply training data (e.g., prompts 248 and corresponding completions) to the machine learning models 268 to configure (e.g., train, modify, update, fine-tune, etc.) the machine learning models 268. The training manager 244 can control training by the model configuration processor 264 based on model tuning parameters in the model tuning database 256, such as to control various hyperparameters for training. In various implementations, the system 200 can use the training management system 240 to configure the machine learning models 268 in a similar manner as described with reference to the second model 116 of FIG. 1, such as to train the machine learning models 268 using any of various data or combinations of data from the data repository 204.

### Application Session Management

FIG. 3 depicts an example of the system 200, in which the system 200 can perform operations to implement at least one application session 308 for a client device 304. For example, responsive to configuring the machine learning models 268, the system 200 can generate data for presentation by the client device 304 (including generating data responsive to information received from the client device 304) using the at least one application session 308 and the one or more machine learning models 268.

The client device 304 can be a device of a user, such as a technician or building manager. The client device 304 can include any of various wireless or wired communication interfaces to communicate data with the model system 260, such as to provide requests to the model system 260 indicative of data for the machine learning models 268 to generate, and to receive outputs from the model system 260. The client device 304 can include various user input and output devices to facilitate receiving and presenting inputs and outputs.

In some implementations, the system 200 provides data to the client device 304 for the client device 304 to operate the at least one application session 308. The application session 308 can include a session corresponding to any of the applications 120 described with reference to FIG. 1. For example, the client device 304 can launch the application session 308 and provide an interface to request one or more prompts. Responsive to receiving the one or more prompts, the application session 308 can provide the one or more prompts as input to the machine learning model 268. The machine learning model 268 can process the input to generate a completion, and provide the completion to the application session 308 to present via the client device 304. In some implementations, the application session 308 can iteratively generate completions using the machine learning models 268. For example, the machine learning models 268 can receive a first prompt from the application session 308, determine a first completion based on the first prompt and provide the first completion to the application session 308, receive a second prompt from the application session 308, determine a second completion based on the second prompt (which may include at least one of the first prompt or the first completion concatenated to the second prompt), and provide the second completion to the application session 308.

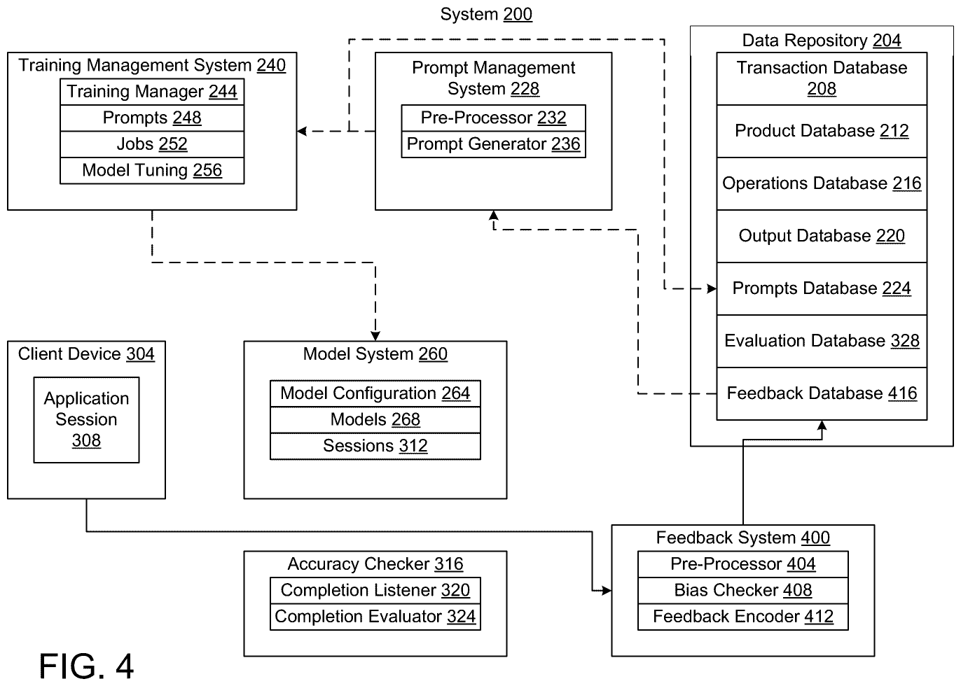

In some implementations, the model system 260 includes at least one sessions database 312. The sessions database 312 can maintain records of application session 308 implemented by client devices 304. For example, the sessions database 312 can include records of prompts provided to the machine learning models 268 and completions generated by the machine learning models 268. As described further with reference to FIG. 4, the system 200 can use the data in the sessions database 312 to fine-tune or otherwise update the machine learning models 268.

### Completion Checking

In some implementations, the system 200 includes an accuracy checker 316. The accuracy checker 316 can include one or more rules, heuristics, logic, policies, algorithms, functions, machine learning models, neural networks, scripts, or various combinations thereof to perform operations including evaluating performance criteria regarding the completions determined by the model system 260. For example, the accuracy checker 316 can include at least one completion listener 320. The completion listener 320 can receive the completions determined by the model system 260 (e.g., responsive to the completions being generated by the machine learning model 268 and/or by retrieving the completions from the sessions database 312).

The accuracy checker 316 can include at least one completion evaluator 324. The completion evaluator 324 can evaluate the completions (e.g., as received or retrieved by the completion listener 320) according to various criteria. In some implementations, the completion evaluator 324 evaluates the completions by comparing the completions with corresponding data from the data repository 204. For example, the completion evaluator 324 can identify data of the data repository 204 having similar text as the prompts and/or completions (e.g., using any of various natural language processing algorithms), and determine whether the data of the completions is within a range of expected data represented by the data of the data repository 204.

In some implementations, the accuracy checker 316 can store an output from evaluating the completion (e.g., an indication of whether the completion satisfies the criteria) in an evaluation database 328. For example, the accuracy checker 316 can assign the output (which may indicate at least one of a binary indication of whether the completion satisfied the criteria or an indication of a portion of the completion that did not satisfy the criteria) to the completion for storage in the evaluation database 328, which can facilitate further training of the machine learning models 268 using the completions and output.

### Feedback Training

FIG. 4 depicts an example of the system 200 that includes a feedback system 400, such as a feedback aggregator. The feedback system 400 can include one or more rules, heuristics, logic, policies, algorithms, functions, machine learning models, neural networks, scripts, or various combinations thereof to perform operations including preparing data for updating and/or updating the machine learning models 268 using feedback corresponding to the application sessions 308, such as feedback received as user input associated with outputs presented by the application sessions 308. The feedback system 400 can incorporate features of the feedback repository 124 and/or feedback trainer 128 described with reference to FIG. 1.

The feedback system 400 can receive feedback (e.g., from the client device 304) in various formats. For example, the feedback can include any of text, speech, audio, image, and/or video data. The feedback can be associated (e.g., in a data structure generated by the application session 308) with the outputs of the machine learning models 268 for which the feedback is provided. The feedback can be received or extracted from various forms of data, including external data sources such as manuals, service reports, or Wikipedia-type documentation.

In some implementations, the feedback system 400 includes a pre-processor 404. The pre-processor 404 can perform any of various operations to modify the feedback for further processing. For example, the pre-processor 404 can incorporate features of, or be implemented by, the pre-processor 232, such as to perform operations including filtering, compression, tokenizing, or translation operations (e.g., translation into a common language of the data of the data repository 204).

The feedback system 400 can include a bias checker 408. The bias checker 408 can evaluate the feedback using various bias criteria, and control inclusion of the feedback in a feedback database 416 (e.g., a feedback database 416 of the data repository 204 as depicted in FIG. 4) according to the evaluation. The bias criteria can include, for example and without limitation, criteria regarding qualitative and/or quantitative differences between a range or statistic measure of the feedback relative to actual, expected, or validated values.

The feedback system 400 can include a feedback encoder 412. The feedback encoder 412 can process the feedback (e.g., responsive to bias checking by the bias checker 408) for inclusion in the feedback database 416. For example, the feedback encoder 412 can encode the feedback as values corresponding to outputs scoring determined by the model system 260 while generating completions (e.g., where the feedback indicates that the completion presented via the application session 308 was acceptable, the feedback encoder 412 can encode the feedback by associating the feedback with the completion and assigning a relatively high score to the completion).

As indicated by the dashed arrows in FIG. 4, the feedback can be used by the prompt management system 228 and training management system 240 to further update one or more machine learning models 268. For example, the prompt management system 228 can retrieve at least one feedback (and corresponding prompt and completion data) from the feedback database 416, and process the at least one feedback to determine a feedback prompt and feedback completion to provide to the training management system 240 (e.g., using pre-processor 232 and/or prompt generator 236, and assigning a score corresponding to the feedback to the feedback completion). The training manager 244 can provide instructions to the model system 260 to update the machine learning models 268 using the feedback prompt and the feedback completion, such as to perform a fine-tuning process using the feedback prompt and the feedback completion. In some implementations, the training management system 240 performs a batch process of feedback-based fine tuning by using the prompt management system 228 to generate a plurality of feedback prompts and a plurality of feedback completion, and providing instructions to the model system 260 to perform the fine-tuning process using the plurality of feedback prompts and the plurality of feedback completions.

### Data Filtering and Validation Systems

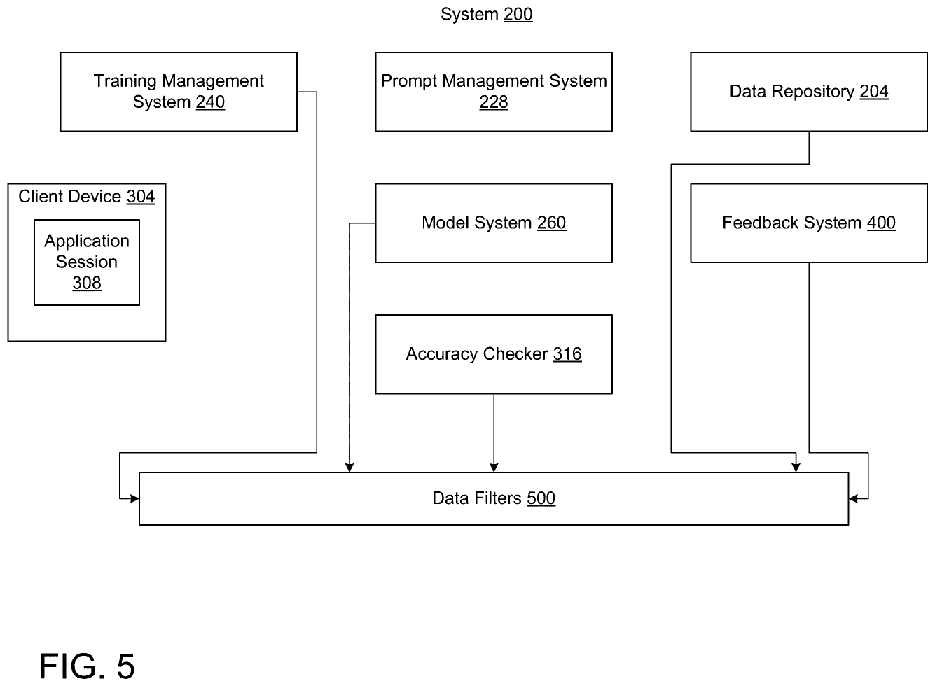

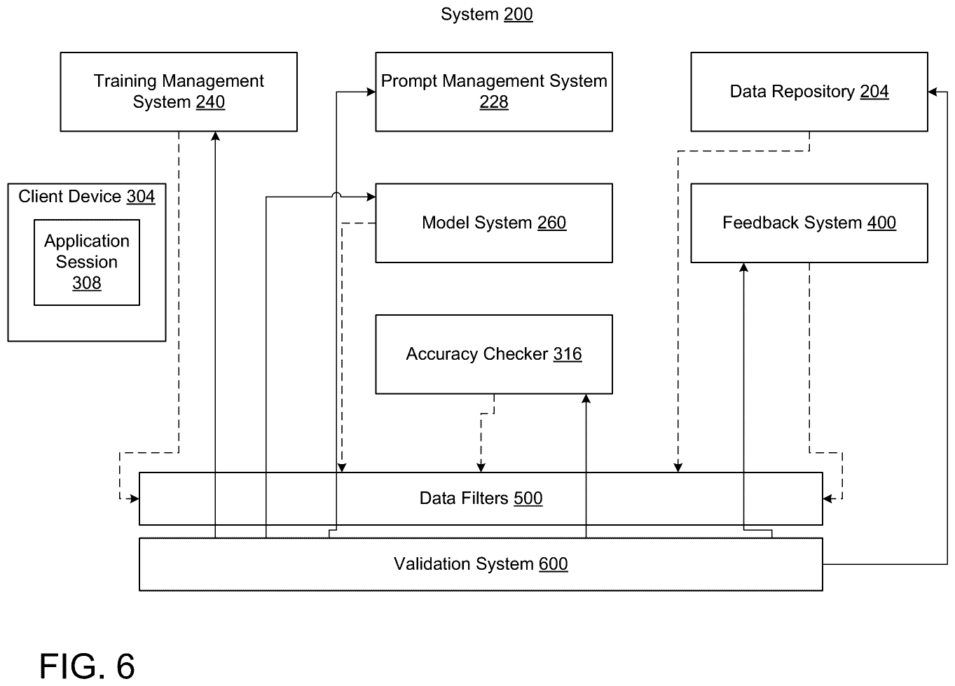

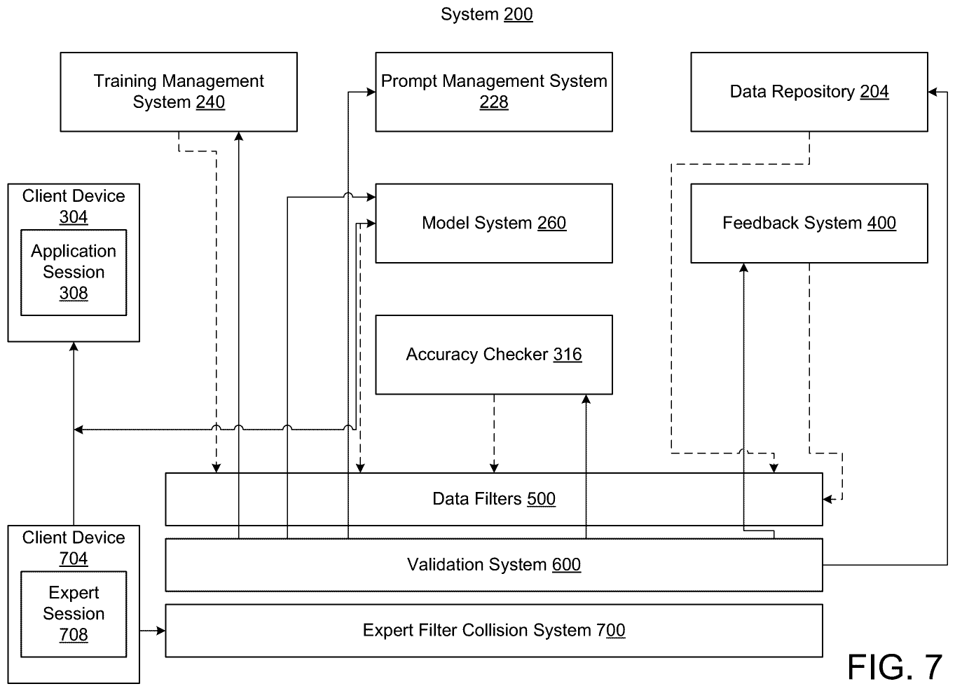

FIG. 5 depicts an example of the system 200, where the system 200 can include one or more data filters 500 (e.g., data validators). The data filters 500 can include any one or more rules, heuristics, logic, policies, algorithms, functions, machine learning models, neural networks, scripts, or various combinations thereof to perform operations including modifying data processed by the system 200 and/or triggering alerts responsive to the data not satisfying corresponding criteria, such as thresholds for values of data. Various data filtering processes described with reference to FIG. 5 (as well as FIGS. 6 and 7) can enable the system 200 to implement timely operations for improving the precision and/or accuracy of completions or other information generated by the system 200 (e.g., including improving the accuracy of feedback data used for fine-tuning the machine learning models 268). The data filters 500 can allow for interactions between various algorithms, models, and computational processes.

For example, the data filters 500 can be used to evaluate data relative to thresholds relating to data including, for example and without limitation, acceptable data ranges, setpoints, temperatures, pressures, flow rates (e.g., mass flow rates), or vibration rates for an item of equipment. The threshold can include any of various thresholds, such as one or more of minimum, maximum, absolute, relative, fixed band, and/or floating band thresholds.

The data filters 500 can enable the system 200 to detect when data, such as prompts, completions, or other inputs and/or outputs of the system 200, collide with thresholds that represent realistic behavior or operation or other limits of items of equipment. For example, the thresholds of the data filters 500 can correspond to values of data that are within feasible or recommended operating ranges. In some implementations, the system 200 determines or receives the thresholds using models or simulations of items of equipment, such as plant or equipment simulators, chiller models, HVAC-R models, refrigeration cycle models, etc. The system 200 can receive the thresholds as user input (e.g., from experts, technicians, or other users). The thresholds of the data filters 500 can be based on information from various data sources. The thresholds can include, for example and without limitation, thresholds based on information such as equipment limitations, safety margins, physics, expert teaching, etc. For example, the data filters 500 can include thresholds determined from various models, functions, or data structures (e.g., tables) representing physical properties and processes, such as physics of psychometrics, thermodynamics, and/or fluid dynamics information.

The system 200 can determine the thresholds using the feedback system 400 and/or the client device 304, such as by providing a request for feedback that includes a request for a corresponding threshold associated with the completion and/or prompt presented by the application session 308. For example, the system 200 can use the feedback to identify realistic thresholds, such as by using feedback regarding data generated by the machine learning models 268 for ranges, setpoints, and/or start-up or operating sequences regarding items of equipment (and which can thus be validated by human experts). In some implementations, the system 200 selectively requests feedback indicative of thresholds based on an identifier of a user of the application session 308, such as to selectively request feedback from users having predetermined levels of expertise and/or assign weights to feedback according to criteria such as levels of expertise.

In some implementations, one or more data filters 500 correspond to a given setup. For example, the setup can represent a configuration of a corresponding item of equipment (e.g., configuration of a chiller, etc.). The data filters 500 can represent various thresholds or conditions with respect to values for the configuration, such as feasible or recommendation operating ranges for the values. In some implementations, one or more data filters 500 correspond to a given situation. For example, the situation can represent at least one of an operating mode or a condition of a corresponding item of equipment.

FIG. 5 depicts some examples of data (e.g., inputs, outputs, and/or data communicated between nodes of machine learning models 268) to which the data filters 500 can be applied to evaluate data processed by the system 200 including various inputs and outputs of the system 200 and components thereof. This can include, for example and without limitation, filtering data such as data communicated between one or more of the data repository 204, prompt management system 228, training management system 240, model system 260, client device 304, accuracy checker 316, and/or feedback system 400. For example, the data filters 500 (as well as validation system 600 described with reference to FIG. 6 and/or expert filter collision system 700 described with reference to FIG. 7) can receive data outputted from a source (e.g., source component) of the system 200 for receipt by a destination (e.g., destination component) of the system 200, and filter, modify, or otherwise process the outputted data prior to the system 200 providing the outputted data to the destination. The sources and destinations can include any of various combinations of components and systems of the system 200.

The system 200 can perform various actions responsive to the processing of data by the data filters 500. In some implementations, the system 200 can pass data to a destination without modifying the data (e.g., retaining a value of the data prior to evaluation by the data filter 500) responsive to the data satisfying the criteria of the respective data filter(s) 500. In some implementations, the system 200 can at least one of (i) modify the data or (ii) output an alert responsive to the data not satisfying the criteria of the respective data filter(s) 500. For example, the system 200 can modify the data by modifying one or more values of the data to be within the criteria of the data filters 500.

In some implementations, the system 200 modifies the data by causing the machine learning models 268 to regenerate the completion corresponding to the data (e.g., for up to a predetermined threshold number of regeneration attempts before triggering the alert). This can enable the data filters 500 and the system 200 selectively trigger alerts responsive to determining that the data (e.g., the collision between the data and the thresholds of the data filters 500) may not be repairable by the machine learning model 268 aspects of the system 200.

The system 200 can output the alert to the client device 304. The system 200 can assign a flag corresponding to the alert to at least one of the prompt (e.g., in prompts database 224) or the completion having the data that triggered the alert.

FIG. 6 depicts an example of the system 200, in which a validation system 600 is coupled with one or more components of the system 200, such as to process and/or modify data communicated between the components of the system 200. For example, the validation system 600 can provide a validation interface for human users (e.g., expert supervisors, checkers) and/or expert systems (e.g., data validation systems that can implement processes analogous to those described with reference to the data filters 500) to receive data of the system 200 and modify, validate, or otherwise process the data. For example, the validation system 600 can provide to human expert supervisors, human checkers, and/or expert systems various data of the system 200, receive responses to the provided data indicating requested modifications to the data or validations of the data, and modify (or validate) the provided data according to the responses.

For example, the validation system 600 can receive data such as data retrieved from the data repository 204, prompts outputted by the prompt management system 228, completions outputted by the model system 260, indications of accuracy outputted by the accuracy checker 316, etc., and provide the received data to at least one of an expert system or a user interface. In some implementations, the validation system 600 receives a given item of data prior to the given item of data being processed by the model system 260, such as to validate inputs to the machine learning models 268 prior to the inputs being processed by the machine learning models 268 to generate outputs, such as completions.

In some implementations, the validation system 600 validates data by at least one of (i) assigning a label (e.g., a flag, etc.) to the data indicating that the data is validated or (ii) passing the data to a destination without modifying the data. For example, responsive to receiving at least one of a user input (e.g., from a human validator/supervisor/expert) that the data is valid or an indication from an expert system that the data is valid, the validation system 600 can assign the label and/or provide the data to the destination.

The validation system 600 can selectively provide data from the system 200 to the validation interface responsive to operation of the data filters 500. This can enable the validation system 600 to trigger validation of the data responsive to collision of the data with the criteria of the data filters 500. For example, responsive to the data filters 500 determining that an item of data does not satisfy a corresponding criteria, the data filters 500 can provide the item of data to the validation system 600. The data filters 500 can assign various labels to the item of data, such as indications of the values of the thresholds that the data filters 500 used to determine that the item of data did not satisfy the thresholds. Responsive to receiving the item of data from the data filters 500, the validation system 600 can provide the item of data to the validation interface (e.g., to a user interface of client device 304 and/or application session 308; for comparison with a model, simulation, algorithm, or other operation of an expert system) for validation. In some implementations, the validation system 600 can receive an indication that the item of data is valid (e.g., even if the item of data did not satisfy the criteria of the data filters 500) and can provide the indication to the data filters 500 to cause the data filters 500 to at least partially modify the respective thresholds according to the indication.

In some implementations, the validation system 600 selectively retrieves data for validation where (i) the data is determined or outputted prior to use by the machine learning models 268, such as data from the data repository 204 or the prompt management system 228, or (ii) the data does not satisfy a respective data filter 500 that processes the data. This can enable the system 200, the data filters 500, and the validation system 600 to update the machine learning models 268 and other machine learning aspects (e.g., generative AI aspects) of the system 200 to more accurately generate data and completions (e.g., enabling the data filters 500 to generate alerts that are received by the human experts/expert systems that may be repairable by adjustments to one or more components of the system 200).

FIG. 7 depicts an example of the system 200, in which an expert filter collision system 700 (“expert system” 700) can facilitate providing feedback and providing more accurate and/or precise data and completions to a user via the application session 308. For example, the expert system 700 can interface with various points and/or data flows of the system 200, as depicted in FIG. 7, where the system 200 can provide data to the expert filter collision system 700, such as to transmit the data to a user interface and/or present the data via a user interface of the expert filter collision system 700 that can be accessed via an expert session 708 of a client device 704. For example, via the expert session 708, the expert system 700 can enable functions such as receiving inputs for a human expert to provide feedback to a user of the client device 304; a human expert to guide the user through the data (e.g., completions) provided to the client device 304, such as reports, insights, and action items; a human expert to review and/or provide feedback for revising insights, guidance, and recommendations before being presented by the application session 308; a human expert to adjust and/or validate insights or recommendations before they are viewed or used for actions by the user; or various combinations thereof. In some implementations, the expert system 700 can use feedback received via the expert session as inputs to update the machine learning models 268 (e.g., to perform fine-tuning).

In some implementations, the expert system 700 retrieves data to be provided to the application session 308, such as completions generated by the machine learning models 268. The expert system 700 can present the data via the expert session 708, such as to request feedback regarding the data from the client device 704. For example, the expert system 700 can receive feedback regarding the data for modifying or validating the data (e.g., editing or validating completions). In some implementations, the expert system 700 requests at least one of an identifier or a credential of a user of the client device 704 prior to providing the data to the client device 704 and/or requesting feedback regarding the data from the expert session 708. For example, the expert system 700 can request the feedback responsive to determining that the at least one of the identifier or the credential satisfies a target value for the data. This can allow the expert system 700 to selectively identify experts to use for monitoring and validating the data.

In some implementations, the expert system 700 facilitates a communication session regarding the data, between the application session 308 and the expert session 708. For example, the expert system 700, responsive to detecting presentation of the data via the application session 308, can request feedback regarding the data (e.g., user input via the application session 308 for feedback regarding the data), and provide the feedback to the client device 704 to present via the expert session 708. The expert session 708 can receive expert feedback regarding at least one of the data or the feedback from the user to provide to the application session 308. In some implementations, the expert system 700 can facilitate any of various real-time or asynchronous messaging protocols between the application session 308 and expert session 708 regarding the data, such as any of text, speech, audio, image, and/or video communications or combinations thereof. This can allow the expert system 700 to provide a platform for a user receiving the data (e.g., customer or field technician) to receive expert feedback from a user of the client device 704 (e.g., expert technician). In some implementations, the expert system 700 stores a record of one or more messages or other communications between the sessions 308, 708 in the data repository 204 to facilitate further configuration of the machine learning models 268 based on the interactions between the users of the sessions 308, 708.

### Building Data Platforms and Digital Twin Architectures

Referring further to FIGS. 1-7, various systems and methods described herein can be executed by and/or communicate with building data platforms, including data platforms of building management systems. For example, the data repository 204 can include or be coupled with one or more building data platforms, such as to ingest data from building data platforms and/or digital twins. The client device 304 can communicate with the system 200 via the building data platform, and can feedback, reports, and other data to the building data platform. In some implementations, the data repository 204 maintains building data platform-specific databases, such as to enable the system 200 to configure the machine learning models 268 on a building data platform-specific basis (or on an entity-specific basis using data from one or more building data platforms maintained by the entity).

For example, in some implementations, various data discussed herein may be stored in, retrieved from, or processed in the context of building data platforms and/or digital twins; processed at (e.g., processed using models executed at) a cloud or other off-premises computing system/device or group of systems/devices, an edge or other on-premises system/device or group of systems/devices, or a hybrid thereof in which some processing occurs off-premises and some occurs on-premises; and/or implemented using one or more gateways for communication and data management amongst various such systems/devices. In some such implementations, the building data platforms and/or digital twins may be provided within an infrastructure such as those described in U.S. patent application Ser. No. 17/134,661 filed Dec. 28, 2020, Ser. No. 18/080,360, filed Dec. 13, 2022, Ser. No. 17/537,046 filed Nov. 29, 2021, and Ser. No. 18/096,965, filed Jan. 13, 2023, and Indian patent application No. 202341008712, filed Feb. 10, 2023, the disclosures of which are incorporated herein by reference in their entireties.

### III. Generative AI-Based Systems and Methods for Sensor Plan Generation

As described above, systems and methods in accordance with the present disclosure can use machine learning models, including LLMs and other generative AI models, to ingest data regarding building management systems and equipment in various unstructured and structured formats, and generate completions and other outputs targeted to provide useful information to users. Various systems and methods described herein can use machine learning models to support applications for presenting data with high accuracy and relevance.

### Goal-Based Sensor Plan Generation Using Machine Learning Models

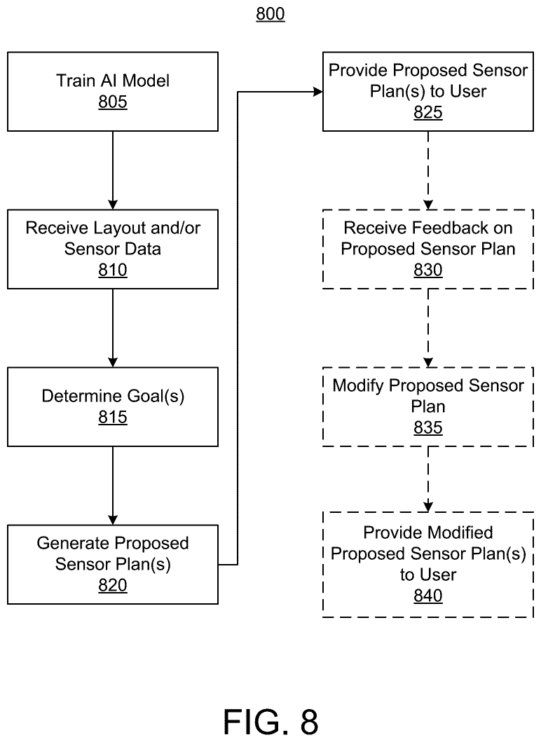

FIG. 8 depicts an example of a method 800 for goal-based sensor plan generation using machine learning models, according to an example embodiment. The method 800 can be performed using various devices and systems described herein, including but not limited to the systems 100, 200 or one or more components thereof. Various aspects of the method 800 can be implemented using one or more devices or systems that are communicatively coupled with one another, including in client-server, cloud-based, or other networked architectures.

For the purposes of the present disclosure, the term “sensor” may refer to any sensing device that may be utilized to collect information relating to a surrounding area. For example, in some instances, a “sensor” may include an audio sensor or recorder, a video and/or image capturing device, a light sensor, a motion sensor, a temperature sensor, a wireless signal sensor (e.g., a PowerG detection sensor, a Bluetooth detection sensor, a Wi-Fi sensor), an air-quality sensor, a humidity sensor, a virus detection sensor, a particulate detection sensor (e.g., carbon particulate), and/or any other type of sensing device that may be arranged within a building to detect or otherwise monitor one or more aspects of the building.

At step 805, the AI model can be trained. For example, in some instances, the AI model may be a generative large language model (LLM), such as, for example, a pretrained generative transformer model. In some implementations, a model updater (e.g., model updater 108) can apply a variety of training data (e.g., received from data sources 112) relevant to generating a proposed sensor plan as training input to train the AI model to allow for the AI model to autonomously determine goals and generate proposed sensor plans for given spaces within buildings.

For example, in some implementations, the training data may comprise any of floor plan data (e.g., 2D or 3D floor plans) of one or more buildings, sensor layout data of the one or more buildings, energy efficiency data of the one or more buildings, provisioning cost data (e.g., pertaining to the cost of outfitting a given space with proposed equipment associated with a proposed sensor plan) of the one or more buildings, operational cost data (e.g., the cost of operating the proposed sensor plan) of the one or more buildings, air quality data of the one or more buildings, sustainability data of the one or more buildings, building information modeling (BIM) data of the one or more buildings, audio data of the one or more buildings (e.g., captured via a user device walking through one or more areas of a building), photographic data of the one or more buildings (e.g., captured via a user device walking through one or more areas of a building), videographic data of the one or more buildings (e.g., captured via a user device walking through one or more areas of a building), other sensor data (e.g., temperature sensor, motion sensor) of the one or more buildings, regulatory compliance data, or user feedback data.

In some embodiments, the training data may comprise one or more device manuals, troubleshooting guides, or other authenticated and/or validated documentation having one or more of installation instructions, placement instructions, functionality instructions and/or explanations pertaining to one or more devices (e.g., equipment, sensors) within a given space. In some instances, the device manuals, troubleshooting guides, and/or other documentation may include specific positioning instructions. For example, the positioning instructions may indicate that a temperature sensor should not be placed within a certain distance (e.g., 5 feet) from an exterior wall or window, an air conditioning or heating discharge stream, in a blocked area (e.g., behind a door), or near a device that generates heat (e.g., a coffee maker, a light bulb, a vending machine, a radiator) because it may affect the accuracy of the temperature sensor. Similarly, the positioning instructions may indicate that a sensor should not be placed within a certain distance of a device that generates or produces electromagnetic interference. For example, wireless sensors can be interfered with by other products or objects that generate or otherwise create electromagnetic interference (e.g., a microwave, a Wi-Fi access point, a variable speed drive, large metallic objects).

The positioning instructions may additionally specify where a sensor should be placed (e.g., at least 4 feet off of the ground). In some instances, the positioning instructions may be implicit or explicit. For example, the device manual or other documentation may implicitly provide positioning instructions by indicating that a given sensor may experience inaccuracies or go outside its tolerances if it is positioned in a certain way (e.g., too close to an exterior wall, too close to a device creating electromagnetic interference).

In some instances, the functionality instructions and/or explanations pertaining to the one or more devices may include information relating to heat generation of the devices, electromagnetic radiation generated by the devices, and/or any other pertinent information that may be relevant to or otherwise affect the potential accuracy of sensors within a given space of a building. Accordingly, the system 200 may be configured to utilize information about various devices in a given space to determine which devices could interfere with sensor functionality or accuracy within the space and take those inferences into account when generating the sensor plan layouts described herein.

In some instances, the system 200 is configured to ingest images, pictures, diagrams, videos (e.g., if the manual or other validated documentation is digital or otherwise includes videographic information), and/or text from the device manuals or other documentation and utilize one or more multimodal models (e.g., a GPT-based multimodal model) to translate the images, pictures, diagrams, videos, and/or text into parameters to be used to generate proposed sensor layouts, as described herein.

In some embodiments, the training data may comprise one or more service reports and/or other service call information (e.g., transcripts, text-based chat histories, shared images, shared videos, audio information, etc.) pertaining to the functioning or malfunctioning of various building equipment (e.g., sensors) and corresponding service actions taken to resolve functionality issues (e.g., accuracy issues) associated with the building equipment. These service reports and/or other service call information may include expert feedback, troubleshooting, and/or resolutions pertaining to a variety of device functionality issues. In some instances, the service reports and/or other service call information may include specific installation and/or positioning instructions for resolving inaccurate sensor readings or other sensor malfunctions. As one example, during a service call, a service technician may ask where a given malfunctioning sensor is installed and, if the sensor is installed in a location that is prone to malfunctioning or inaccuracy (e.g., a temperature sensor installed near an exterior window), the service technician may suggest repositioning the sensor to another location. The user or customer placing the service call may then report (e.g., verbally, via a text-based chat interface) the outcome (e.g., the sensor inaccuracy has been resolved) to the service technician during the service call. Accordingly, the system 200 may be configured to utilize data from the service reports and/or other service call information (e.g., recommended solutions and/or results of those recommendations), in combination with information about various devices and/or objects in a given space, to determine which objects, devices, and/or other issues generally could interfere with sensor functionality, accuracy, and/or measurement validity within the space and take those inferences into account when generating the sensor plan layouts described herein.

At step 810, data associated with the layout of a space within the building and/or sensors within the building can be received. In some implementations, similar data may be received pertaining to a building of interest as was used to train the AI models. For example, in some implementations, the data can include any of a layout of a given space of the building, equipment within the space (e.g., a current sensor layout within the space), and/or a purpose of the space (e.g., storage, meeting space, office space). In some implementations, the data may additionally or alternatively include any type of data that may be ingested from a building information model (BIM) of the building or a building floorplan (e.g., a 2D or 3D floorplan) of the building.

In some implementations, the data is collected via one or more data collection devices as the data collection devices are physically moved throughout the building. For example, in some instances, the one or more data collection devices may be wearable or user-carried devices (e.g., smartwatch, smartphone, backpack device) that are walked or otherwise carried throughout the building by a user to collect the necessary data. In some instances, the one or more data collection devices may include an augmented reality (AR) device that captures data as the user walks throughout the building. In some other instances, the one or more data collection devices may instead be autonomously moved throughout the building via a drone or other autonomously guided moveable device (e.g., similar to a robot vacuum). In some instances, the one or more data collection devices may themselves be configured to autonomously move throughout the building.

In some implementations, the one or more data collection devices may be any of an audio recording device, a video recording device, a network connectivity sensor, a motion sensor, a temperature sensor (e.g., a temperature sensor associated with a thermostat), or any other type of device configured to collect or otherwise obtain data relating to the building. Accordingly, in some instances, the data may include sounds within the building, images of one or more spaces within the building, videos of one or more spaces within the building, network connectivity data associated with the building, detected signal data (e.g., PowerG data, Wi-Fi data, Bluetooth data) within the building, detected light signals within the building, detected people (e.g., people counting data or occupancy data) within the building, detected motion within the building, detected temperatures within the building, or any other relevant data pertaining to the building. In some instances, the data may include network connectivity data in the form of mesh network data including information on devices and device locations of devices connected to a network (e.g., Wi-Fi, LAN) of the building.

In some instances, the data may include a textual or verbal description of one or more assets or areas within the building. For example, in some instances, a user (e.g., a designated “data collector”) may be prompted to walk to a particular space within a building and describe what they see (either audibly or via a text input). In some instances, this prompt may ask whether certain equipment and/or sensors are present at given locations within the space and/or may request that the user collect data from a particular location within the space that does not yet have sufficient data collected for the AI model to generate the proposed sensor plan discussed below. In some instances, the data may include a drawing of a given space within the building that is provided by a user (e.g., via a touchscreen surface of the client device 304).

In some instances, a user may provide a textual or verbal description of the one or more assets or areas within the building and a text-to-image model may be utilized to provide the user (e.g., via the client device 304) with a generated image of the described assets or areas. The user may then (e.g., via the client device 304) provide feedback (e.g., via a chat-bot or similar communication interface) to adjust or modify the generated image until it provides an accurate depiction of the assets or areas within the building. Then, once the user confirms that the depiction of the assets or areas within the building is accurate, that depiction may be utilized as the data, at step 810.

In some implementations, the data received is correlated with a detected location of the one or more data collection devices within the building at a time when the data is collected by the one or more data collection devices. Accordingly, this detected location may be utilized to identify or otherwise locate various equipment and/or other assets within the building.

In some implementations, one or more pieces of equipment may be identified within the building based on one or more predetermined test operation sounds emitted by the one or more pieces of equipment. For example, in some instances, various pieces of equipment within the building may be configured to emit one or more human-audible (e.g., a text performed outside of business hours) or non-human-audible (e.g., outside a human's audible range) sounds that are modulated to embed information about the corresponding pieces of equipment. Accordingly, in some instances, a sound-based data collection device may detect these sounds and use directional and/or intensity characteristics of the sounds to locate and identify various pieces of equipment in the building. In some instances, a similar process may be performed utilizing various light signal emissions instead of sound emissions. For example, various pieces of equipment may be identified and located within the building based on one or more predetermined light signals emitted by the one or more pieces of equipment. In some instances, various devices may be initially detected or discovered using the sound and/or light emissions discussed above, and may then be configured to automatically receive information from and/or transmit information to the data collection device using another wireless communication method (e.g., PowerG, Bluetooth, Wi-Fi).

In some implementations, the systems described herein may utilize the data received from the various data sources to identifying, using the AI model(s), identified equipment within the building, as well as various connections and/or relationships between identified pieces of equipment based on the data. For example, in some instances, based on various images, audio, video, BIM or other data, the systems described herein, using the trained AI models discussed above, may be able to both identify various equipment within the building from, for example, a video feed and to automatically discern how equipment within the building is connected or otherwise related. In some instances, determining these connections or relationships is performed completely autonomously and implicitly based on the received data without explicit input from any user regarding the connections or relationships. In some other instances, the systems described herein may determine predicted connections or relationships between the identified pieces of equipment and instead ask for user-confirmation of the predicted connections or relationships.

In some implementations, after receiving a first amount of data, the systems described herein may determine various additional data to collect to allow for the autonomous generation of a proposed sensor plan. For example, in some instances, the AI model may additionally be trained using a variety of data sufficiency and/or data quality/integrity training data configured to allow the AI model to determine when sufficient and/or adequate (e.g., quality-wise) data has been obtained to make various predictions and/or to generate various proposals. For example, in some such implementations, the data sufficiency and/or data quality/integrity training data may be similar to the various data quality indicators, data quality levels, data health scores, and data health metrics described in U.S. patent application Ser. No. 17/708,661, filed Mar. 30, 2022, Ser. No. 17/708,929, filed Mar. 30, 2022, Ser. No. 17/708,845, filed Mar. 30, 2022, Ser. No. 17/708,970, filed Mar. 30, 2022, Ser. No. 17/708,972, filed Mar. 30, 2022, and Ser. No. 18/117,611, filed Mar. 6, 2023, the disclosures of which are incorporated herein by reference in their entireties.

Accordingly, in some implementations, the systems described herein may utilized the trained AI model to determine that additional data is necessary to allow for the autonomous generation of the proposed sensor plan (or at least to autonomously generate a proposed sensor plan with a predetermined confidence level that the proposed sensor plan is viable). In some instances, the system may then generate a prompt requesting that the additional data be collected and transmit the prompt to a data collection device. In some instances, the prompt may cause the data collection device to automatically collect the additional data (e.g., via a security camera installed within the building or via an autonomously moveable drone-like device). In some other instances, the prompt may be directed toward a user to have the user collect the additional data using the data collection device. In any case, the system may then receive the additional data in response to the prompt and use the original data and the additional data (in addition to a goal for a given space within the building) to generate the proposed sensor plan, as will be discussed in detail below.

At step 815, a goal (or multiple goals) for a sensor plan within the space can be determined. In some implementations, the goal(s) may include any of a sensing accuracy and/or validity (e.g., maximizing sensor accuracy and/or validity), a sensor coverage (e.g., maximizing sensor coverage, such as video surveillance coverage), a cost for provisioning the space with building equipment associated with a proposed sensor plan (e.g., reducing or minimizing the cost), a cost for operating the space having the building equipment associated with the proposed sensor plan (e.g., reducing or minimizing the cost), an air quality within the space (e.g., increasing or maximizing the air quality), energy efficiency of the space (e.g., increasing or maximizing energy efficiency), a sustainability or carbon emissions of the space (e.g., improving or maximizing sustainability, or reducing or minimizing a carbon emissions level, for the space), compliance with one or more regulatory requirements, satisfying a purpose of the space, meeting an operational functionality requirement (e.g., allowing the space to operate as intended), and/or any other suitable goal for the space. In some instances, the goal may be a combination of goals and/or a weighted combination of goals (e.g., given some goals more weight than other goals based on determined characteristics associated with the space and/or sensors and/or based on received input from a user).

For example, in some implementations, the system may receive user input in the form of unstructured natural language input not conforming to a predetermined format. The system may then, using the AI model (e.g., a generative LLM), determine the goal for the sensor plan within the space based on the user input. In some implementations, the AI model is a generative AI model configured to autonomously determine the goal for the space based on the data. For example, in some instances, the generative AI model may be used to determine that any of a regulatory requirement, a rule, a purpose-based requirement, and/or an operational requirement applies to a given space and/or sensor based on the data. In some implementations, this determination may be performed without user input or any other explicit indications (e.g., explicitly labeled data or metadata) indicating which regulatory requirements, rules, purpose-based requirements, or operational requirements apply to the space and/or the sensor.

In some implementations, as discussed above, the goal may be compliance with one or more regulatory standard requirements or standards. In some instances, the generative AI model is configured to autonomously determining which regulatory standard requirements based on a variety of information pertaining a given space and/or sensor. For example, in some instances, the regulatory requirements or standards that may apply to the space and/or sensor may include any of a FITWELL standard, a RESET standard, a GREENMARK standard, a LEED standard, a WELL standard, an ASHRAE standard, or any other applicable regulatory requirements or standards.

At step 820, a proposed sensor plan (or multiple proposed sensor plans) can be generated. For example, the AI model may be used to autonomously generate the proposed sensor plan(s) for the space based on the received data and the determined goal. In some scenarios, the proposed sensor plan may include a proposed utilization (e.g., an optimal data aggregation from) and/or placement, positioning, or spacing of sensors already present within a given space. In some instances, the proposed sensor plan may additionally or alternatively include a proposed replacement of one or more sensors already present within a given space (e.g., with newer and/or stronger sensors and/or sensors of a different type). In some instances, the proposed sensor plan may additionally or alternatively include a proposed addition of one or more additional sensors to the space (e.g., an entirely new sensor layout plan). In some instances, the proposed sensor plan additionally or alternatively includes a proposed utilization of one or more additional data sources to supplement data from sensors within the space. It will be appreciated that the AI model (e.g., a generative AI model) is capable of generating the proposed sensor plan based on the data and the goal without requiring any manual user intervention.

In some instances, the proposed sensor plan is generated based on a plurality of different goals. Accordingly, generating the proposed sensor plan may include the AI model autonomously solving a multi-variable optimization analysis having a variety of constraints (e.g., goal-based requirements or desires) and control variables (e.g., where to place different sensors, how to lay out equipment within a given space, which sensors currently located within a given space to aggregate data from to obtain a particular output). For example, in some such implementations, the AI model may be trained using sufficient multi-variable optimization training data to allow for the AI model to autonomously utilize similar techniques and/or achieve similarly useful multi-variable optimization results when generating the proposed sensor plan to those techniques and results described in U.S. patent application Ser. No. 17/483,078, filed Sep. 23, 2021, Ser. No. 17/403,669, filed Aug. 16, 2021, Ser. No. 17/826,635, filed May 27, 2022, Ser. No. 16/927,759, filed Jul. 13, 2020, and Ser. No. 16/927,766, filed Jul. 13, 2020, the disclosures of which are incorporated herein by reference in their entireties.

In some implementations, autonomously generating the proposed sensor plan may include autonomously generating a proposed sensor layout from nothing using the AI model alone. In some other implementations, autonomously generating the proposed sensor plan may include autonomously modifying a stored sensor layout based on the data to create the proposed sensor layout.

In some implementations, the system is configured to use the AI model to autonomously generate a plurality of different proposed sensor plans. For example, the plurality of different proposed sensor plans may each have different properties to may be more or less desirable. For example, in some instances, the different proposed sensor plans may have different accuracy and/or validity level, different sensing coverage within a given space (e.g., areas visible to cameras or other visual sensors), different costs for provisioning the space with building equipment associated with the proposed sensor plans, different costs for operating the space using the proposed sensor plans, different energy efficiencies levels, different sustainability levels, different data integrity levels, and/or a variety of other distinct characteristics. Accordingly, by providing a plurality of proposed sensor plans to a user of the system, as will be described below, the user may compare and contrast the different proposed sensor plans generated by the system before deciding which proposed sensor plan to implement or install.

As discussed above, in some instances, a goal associated with the space may be to comply with various regulatory requirements. Accordingly, in these instances, the system is configured to generate one or more proposed sensor plans including sensor layouts that meet the various regulatory requirements that apply to the space, while also satisfying any other determined goals associated with the space.

At step 825, the proposed sensor plan(s) can be provided to a user. For example, in some instances, the proposed sensor plan(s) may be provided to the user via a user device (e.g., the client device 304) or other computing system running an application (e.g., application 120). In some instances, providing the proposed sensor plan to the user includes providing natural language text or an audio presentation describing the proposed sensor plan. For example, in some instances, the AI model may be used to autonomously generate natural language text or an audio presentation describing the proposed sensor plan. In some instances, providing the proposed sensor plan to the user includes providing an image of a proposed sensor layout to the user via a graphical user interface. For example, in some instances the AI model is a generative AI model or a generative AI-based multi-modal model that is configured to autonomously generate an image of the proposed sensor layout within the building. In some instances, providing the proposed sensor plan to the user includes providing a graphical model of the building showing the proposed sensor plan in a 2D (e.g., 2D floorplan) and/or 3D (e.g., 3D building information model (BIM) representation). For example, in some instances, the AI model is configured to generate an overlay including the proposed sensor plan to be overlaid onto a graphical model of the building produced based on BIM data or a digital twin.

In some instances, the proposed sensor plan may be provided to the user via any of a graphical model viewer, a metaverse representation of the building, a virtual reality representation of the building, or an augmented reality representation of the building. For example, as discussed above, an AI-generated overlay showing the proposed sensor plan may be overlaid onto a graphical model of the building within a graphical model viewer. However, a similar AI-generated overlay could also be overlaid onto a metaverse representation of the building, a virtual reality representation of the building, or an augmented reality representation of the building to visually depict the proposed sensor plan to the user.

In some instances, the AI model(s) may additionally be used to generate a sensor performance index for a given sensor layout. For example, the sensor performance index may take into account or otherwise weigh a variety of factors to generate a score (i.e., the sensor performance index) for the given sensor layout. In some instances, the factors may include, for example, sensor quality, sensor type (e.g., a high-sensitivity or low-sensitivity sensor), number of sensors, predicted sensor layout accuracy and/or validity (e.g., a predicted accuracy of the sensors in the proposed layout arrangement), predicted sensor coverage for the space, etc. Accordingly, using the generated sensor performance index, the user may be provided (e.g., via the client device 304) with an actual performance level or performance index for a current equipment/sensor layout within the space and potential performance levels or performance indexes for any number of proposed sensor plans within the space. In some instances, multiple independent scores or indexes corresponding to multiple independent goals or other characteristics associated with each actual and/or proposed sensor layout may similarly be provided to the user. The user may additionally be provided (e.g., the client device 304) with various cost information (e.g., operational costs, costs of purchasing necessary equipment) for the current and proposed sensor plans to allow the user to directly compare the sensor performance indices and the costs associated with each sensor plan when deciding which sensor plan to implement. For example, in some instances, the sensor performance index, cost information, and/or any other suitable or desired information may be provided as part of an overlay or other display window including the corresponding sensor plan and provided to a user device (e.g., the client device 304) of the user.

At step 830, feedback on the proposed sensor plan can be received. In some implementations, the user may provide (e.g., the client device 304) various feedback pertaining to the proposed sensor plan via a user device or other feedback mechanism. For example, in some instances, the user may provide feedback on the proposed sensor plan via one or more of a conversational chat interface (e.g., a GPT-based chat bot). In some instances, this conversational chat interface may be a typed-word chat using a device keyboard or other text input method. In some other instances, this conversational chat interface may be an audible feedback spoken by the user and received by an audio device associated with the user. In some other instances, the user may provide feedback via any of a user interaction with a dashboard (e.g., a dashboard having various user-selectable goals or constraints for implementing within a given sensor plan), a user interaction with a graphic (e.g., a user selecting a desired sensor location within a graphical model, metaverse, VR, or AR interface), or a user interaction with a chart (e.g., user-moveable slide bars on an interface). It will be appreciated that, in some instances, the user may provide feedback through a combination of the aforementioned feedback mechanisms and/or other feedback mechanisms, as appropriate for a given scenario.

At step 835, the proposed sensor plan can be modified. In some implementations, after receiving feedback on one or more proposed sensor plans, the AI model may then be utilized to autonomously modify the one or more proposed sensor plan based on the feedback to generate one or more updated proposed sensor plans. This modification may include moving one or more sensors, adding or removing one or more sensors, moving other equipment within the space, adding or removing other equipment within the space, or any other suitable modifications.

At step 840, the modified proposed sensor plan can be provided to the user. For example, the modified proposed sensor plan may be provided to the user in a similar manner to the original proposed sensor plan, as discussed above.

It should be appreciated that, in some instances, the user device (e.g., the client device 304) used to provide the proposed sensor plan(s) and/or modified proposed sensor plan(s) to the user may be the same device used to collect data for generating the proposed sensor plan(s) and/or to provide feedback on the proposed sensor plan(s). For example, in some instances, a user may walk around a given space in a building to collect data (e.g., video data, audio data, network connectivity data, etc.) pertaining to the space, receive an autonomously generated proposed sensor plan for the space, provide feedback on the proposed sensor plan, and receive a modified proposed sensor plan for the space, all using the same user device (e.g., the client device 304).

In some instances, the AI model may be further configured to determine whether existing data sources are capable of generating desired predictive information pertaining to areas within the building that are out of range of presently installed sensors or that would be out of range of any new arrangement of sensors included in a proposed sensor plan. In these instances, upon determining that existing data sources are not capable of generating the desired predictive information, the AI model may further determine whether activating one or more additional AI models would allow for the generation of the desired predictive information. Upon determining that activating one or more additional AI models would allow for the generation of the desired predictive information, the AI model may further determine whether the one or more additional AI models require additional sensors to function properly. Upon determining that the one or more additional AI models do not require additional sensors, the system may then activate the one or more additional AI models. However, if the one or more additional AI models do require additional sensors, the system may generate a notification of the required additional sensors and provide the notification to the user.

Similarly, in some instances, the AI models may be configured to determine various functionalities that may be implemented within a given space or building based on a current sensor layout and/or one or more proposed sensor layouts. For example, in some instances, the functionality of certain smart building features may be dependent on a sensor layout within a given area. Accordingly, in some instances, the AI models may be configured to determine which functionalities are currently available based on a current sensor layout, which additional functionalities could be provided for the space or building by adding or rearranging sensors within the space or building, and what the cost of updating the space or building to include the additional or re-positioned sensors to provide the additional functionalities would cost. This information may similarly be provided to the user (e.g., via the client device 304) to allow for the user to better understand the effects of adding, rearranging, or retaining the current layout of the sensors within the space or building. Various examples of sensor-dependent functionalities (e.g., smart building features) and methods for adding and positioning sensors to provide additional sensor-dependent functionalities are described in detail in U.S. patent application Ser. No. 18/215,453, filed Jun. 28, 2023, the entire disclosure of which is incorporated by reference herein.

Accordingly, the systems and methods described herein allow for a user (e.g., a building manager, a building planner) to provide information pertaining to a building layout and to receive various proposed sensor plans based on goals for a given space withing the building. In some instances, the goals can be explicitly provided (e.g., “I want to maximize energy efficiency within the building”). In other instances, the goals can be implicitly provided and/or inferred from characteristics associated with a given space (e.g., a given building is a health-related facility and is thus subject to certain sensor-related regulatory requirements).

As one example, a user may provide floor plans of a building and indicate that their goal is to optimize energy usage by updating heating and/or cooling provided to spaces within the building based on occupancy within those spaces. Accordingly, the AI models described herein may generate and provide the user with one or more proposed sensor plans (e.g., occupancy sensor layouts) for the building that are configured to allow for the building to automatically regulate the heating and/or cooling provided to spaces when the spaces are occupied or not occupied. As another example, the user may indicate that their goal is to maximize (or significantly increase) video surveillance coverage within a certain space or certain spaces within the building. Accordingly, the AI models described herein may generate and provide the user with one or more proposed sensor plans (e.g., camera layouts) that are configured to provide a maximum (or significantly increased) video surveillance coverage. As yet another example, a user may want to ensure accurate temperature detection within a building (e.g., to avoid fire issues associated with heat caused by electrical cabling). Accordingly, the AI models described herein may generate and provide the user with one or more propose one or more temperature sensor plans that avoid placing temperature sensors in locations where there could be accuracy issues (e.g., away from exterior windows, away from air conditioning and/or heating discharge stream).

In some instances, the systems and methods described herein may allow for the user to provide various information in the context of a chat-like discussion (e.g., via a text-based or verbally activated chat-bot). As one use-case example, a user may provide an explanation of a floor plan of a building verbally to a user device (e.g., the client device 304) and indicate that they wish to incorporate occupancy sensing within a given space. The AI models described herein may then generate and provide an indication to the user (e.g., via the client device 304) indicating that there are several options for occupancy sensors and provide various information to the user (e.g., cost, indications of which sensors are wired or wireless, performance levels). The user may then indicate (e.g., via the client device 304) which of the sensor options they would like to use. In some instances, information associated with a given sensor may be pulled from a given sensor model's engineering data (e.g., installation manuals, instruction manuals, operating procedure guides) and provided to the user before, during, or after the user chooses which sensor they want to use. In some instances, if the AI models have not been trained based on a specific sensor, the information associated with the sensor may be inferred by the AI models based on engineering data of other similar sensors. In either case, The AI models described herein may then generate and provide one or more proposed sensor layouts using the selected occupancy sensors to the user (e.g., via the client device 304).

Beneficially, the generative AI models provide multi-modal analysis capabilities that allow for information from a plurality of differing sources (e.g., floor plans, sensor data, device manuals, verbal feedback and instructions, image and video information, etc.) to be combined and translated into parameters to be utilized when generating proposed sensor plans. Additionally, another benefit of the generative AI models described herein, as compared to non-generative neural networks, is that the generative AI models can ingest information (e.g., user manuals) for a particular sensor and, in addition to utilizing that information directly, infer aspects about placing other sensors (e.g., from other manufacturers) for which the generative AI models have not been trained on (e.g., based on similar sensor characteristics and/or functionality).

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the exemplary embodiments without departing from the scope of the present disclosure.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general purpose computer, special purpose computer, or special purpose processing machines to perform a certain function or group of functions.

Although the figures show a specific order of method steps, the order of the steps may differ from what is depicted. Also two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

In various implementations, the steps and operations described herein may be performed on one processor or in a combination of two or more processors. For example, in some implementations, the various operations could be performed in a central server or set of central servers configured to receive data from one or more devices (e.g., edge computing devices/controllers) and perform the operations. In some implementations, the operations may be performed by one or more local controllers or computing devices (e.g., edge devices), such as controllers dedicated to and/or located within a particular building or portion of a building. In some implementations, the operations may be performed by a combination of one or more central or offsite computing devices/servers and one or more local controllers/computing devices. All such implementations are contemplated within the scope of the present disclosure. Further, unless otherwise indicated, when the present disclosure refers to one or more computer-readable storage media and/or one or more controllers, such computer-readable storage media and/or one or more controllers may be implemented as one or more central servers, one or more local controllers or computing devices (e.g., edge devices), any combination thereof, or any other combination of storage media and/or controllers regardless of the location of such devices.

What is claimed is:

1. A method comprising:
receiving, by one or more processors, data relating to a layout of a space of a building and/or one or more first sensors of the building;
determining, by the one or more processors using an artificial intelligence (AI) model, a goal for the space based on the data;
autonomously generating, by the one or more processors using the AI model, a proposed sensor plan for the space based on the data and the goal, the proposed sensor plan comprising at least one of utilization and/or placement of the one or more first sensors within the space, addition of one or more second sensors to the space, or utilization of one or more additional data sources to supplement data from the one or more first sensors for the space, wherein autonomously generating the proposed sensor plan comprises generating the proposed sensor plan using the AI model based on the data and the goal without requiring manual user intervention; and
providing, by the one or more processors, the proposed sensor plan to a user.

2. The method of claim 1, wherein the AI model comprises a generative large language model (LLM), and wherein determining the goal comprises:
receiving, by the one or more processors using the generative LLM, user input comprising unstructured natural language input not conforming to a predetermined format; and
determining, by the one or more processors using the generative LLM, the goal from the unstructured natural language input.

3. The method of claim 1, further comprising:
receiving, by the one or more processors, sensor plan training data comprising one or more of floor plan data of one or more buildings, sensor layout data of the one or more buildings, energy efficiency data of the one or more buildings, provisioning cost data of the one or more buildings, operational cost data of the one or more buildings, air quality data of the one or more buildings, sustainability data of the one or more buildings, building information modeling (BIM) data of the one or more buildings, audio data of the one or more buildings, photographic data of the one or more buildings, videographic data of the one or more buildings, sensor data of the one or more buildings, regulatory compliance data, user feedback data, device manual information associated with one or more devices configured to be installed or placed within the one or more buildings, or service report information associated with building equipment malfunctions and resolutions; and
training, by the one or more processors, the AI model using the sensor plan training data.

4. The method of claim 1, further comprising:
receiving, by the one or more processors, feedback on the proposed sensor plan from the user, the feedback provided via at least one of a conversational chat interface, a user interaction with a dashboard, a user interaction with a graphic, or a user interaction with a chart;
autonomously modifying, by the one or more processors using the AI model, the proposed sensor plan based on the feedback; and
providing, by the one or more processors, the modified proposed sensor plan to the user.

5. The method of claim 1, further comprising:
generating, by the one or more processors, a graphical model of the building showing the proposed sensor plan;
providing, by the one or more processors, the graphical model of the building to the user via a user interface; and
receiving, by the one or more processors, feedback pertaining to the proposed sensor plan from the user via the user interface.

6. The method of claim 1, wherein the data is collected by one or more data collection devices as the one or more data collection devices are moved throughout the building, the one or more data collection devices comprising one or more of a wearable or user-carried device or an automated moving sensor.

7. The method of claim 1, further comprising:
subsequent to receiving the data, determining, by the one or more processors using the AI model, additional data to collect to autonomously generate the proposed sensor plan;
generating, by the one or more processors, a prompt requesting that the additional data be collected;
transmitting, by the one or more processors, the prompt to a data collection device; and
receiving, by the one or more processors, the additional data in response to the prompt,
wherein the proposed sensor plan is autonomously generated using the AI model based on the data, the additional data, and the goal.

8. The method of claim 1, wherein the data comprises a textual or verbal description of one or more assets or areas within the building.

9. The method of claim 1, further comprising:
identifying, by the one or more processors using the AI model, one or more pieces of equipment within the building based on the data;
determining, by the one or more processors using the AI model, one or more connections or relationships between the one or more pieces of equipment autonomously and implicitly based on the data without explicit input from the user regarding the one or more connections or relationships.

10. The method of claim 1, further comprising:
generating, by the one or more processors using the AI model, a sensor performance index;
determining, by the one or more processors using the AI model, an actual performance level for a current equipment layout within the space using the sensor performance index;
determining, by the one or more processors using the AI model, a potential performance level for the proposed sensor plan using the sensor performance index; and
providing the actual performance level and the potential performance level to the user.

11. A system comprising:
one or more processing circuits having one or more processors and one or more memories, the one or more memories having instructions thereon that, when executed by the one or more processors, cause the one or more processors to:
receive data relating to a layout of a space of a building and/or one or more first sensors of the building;
determine, using an artificial intelligence (AI) model, a goal for the space based on the data;
autonomously generate, using the AI model, a proposed sensor plan for the space based on the data and the goal, the proposed sensor plan comprising at least one of utilization and/or placement of the one or more first sensors within the space or addition of one or more second sensors to the space, wherein autonomously generating the proposed sensor plan comprises generating the proposed sensor plan using the AI model based on the data and the goal without requiring manual user intervention; and
provide the proposed sensor plan to a user.

12. The system of claim 11, wherein the AI model comprises a generative large language model (LLM), and wherein determining the goal comprises:
receiving, using the generative LLM, user input comprising unstructured natural language input not conforming to a predetermined format; and
determining, using the generative LLM, the goal from the unstructured natural language input.

13. The system of claim 11, wherein the instructions further cause the one or more processors to:
receive sensor plan training data comprising one or more of floor plan data of one or more buildings, sensor layout data of the one or more buildings, building information modeling (BIM) data of the one or more buildings, audio data of the one or more buildings, photographic data of the one or more buildings, videographic data of the one or more buildings, sensor data of the one or more buildings, device manual information associated with one or more devices configured to be installed or placed within the one or more buildings, or service report information associated with building equipment malfunctions and resolutions; and
training, by the one or more processors, the AI model using the sensor plan training data.

14. The system of claim 11, wherein the instructions further cause the one or more processors to:
generate, using the AI model, a sensor performance index;
determine, using the AI model, an actual performance level for a current sensor layout within the space using the sensor performance index;
determine, using the AI model, a potential performance level for the proposed sensor plan using the sensor performance index; and
providing the actual performance level and the potential performance level to the user.

15. The system of claim 14, wherein the sensor performance index is based on or more of a predicted sensor layout accuracy or a predicted sensor coverage for a given space.

16. The system of claim 15, wherein the sensor performance index is based on the predicted sensor layout accuracy, and the predicted sensor layout accuracy is based on at least one of device manual information associated with one or more sensors configured to be installed or placed within one or more buildings, or service report information associated with sensor malfunctions and resolutions.

17. The system of claim 14, wherein the instructions further cause the one or more processors to:
determine a first set of functionalities enabled by the current sensor layout;
determine a second set of functionalities enabled by the proposed sensor plan;
determine a cost of updating the current sensor layout to the proposed sensor plan; and
provide the first set of functionalities, the second set of functionalities, and the cost to the user.

18. A non-transitory computer-readable storage medium having instructions stored thereon that, when executed by one or more processors, cause the one or more processors to:
receive data relating to a layout of a space of a building and/or one or more first sensors of the building;
determine, using a generative artificial intelligence (GAI) model, a goal for the space based on the data;
autonomously generate, using the GAI model, a proposed sensor plan for the space based on the data and the goal, the proposed sensor plan comprising at least one of utilization and/or placement of the one or more first sensors within the space or addition of one or more second sensors to the space, wherein autonomously generating the proposed sensor plan comprises generating the proposed sensor plan using the GAI model based on the data and the goal without requiring manual user intervention; and
provide the proposed sensor plan to a user.

19. The non-transitory computer-readable storage medium of claim 18, wherein the instructions further cause the one or more processors to:
generate a graphical model of the building showing the proposed sensor plan;
provide the graphical model of the building to the user via a user interface;
receive feedback pertaining to the proposed sensor plan from the user via the user interface; and
generate an updated proposed sensor plan based on the proposed sensor plan and the feedback.

20. The non-transitory computer-readable storage medium of claim 18, wherein the instructions further cause the one or more processors to:
identify, the GAI model, one or more pieces of equipment within the building based on the data;
determine, the GAI model, one or more connections or relationships between the one or more pieces of equipment autonomously and implicitly based on the data without explicit input from the user regarding the one or more connections or relationships.
